(19) United States
(12) Patent Application Publication
(10) Pub. No.: US 2010/0248141 A1
(43) Pub. Date: Sep. 30, 2010

(54) LITHOGRAPHIC PRINTING PLATE PRECURSOR AND PLATE MAKING METHOD THEREOF

(76) Inventor: Tomoya SASAKI, Shizuoka (JP)

Correspondence Address: BIRCH STEWART KOLASCH & BIRCH, PO BOX 747, FALLS CHURCH, VA, 22040-0747, US

(21) Appl. No.: 12/749,002

(22) Filed: Mar. 29, 2010

(30) Foreign Application Priority Data
Mar. 30, 2009 (JP) P2009-083713

(51) Int. Cl. G03F 7/004; G03F 7/20

(52) U.S. Cl. 430/280.1; 430/270.1; 430/286.1; 430/302

(57) ABSTRACT

A lithographic printing plate precursor includes a support and an image-recording layer, a non-image area of the image-recording layer is capable of being removed by supplying printing ink and dampening water, and the image-recording layer contains (A) a compound containing two or more isocyanuric acid skeletons each having at least one substituent containing a hydroxy group, (B) an infrared absorbing agent, (C) a radical initiator and (D) a radical polymerizable compound.

### FIELD OF THE INVENTION

The present invention relates to a lithographic printing plate precursor and a plate making method using the same. More particularly, it relates to a lithographic printing plate precursor capable of undergoing a direct plate making by image exposure with laser and a plate making method comprising on-press development of the lithographic printing plate precursor.

### BACKGROUND OF THE INVENTION

In general, a lithographic printing plate is composed of an oleophilic image area accepting ink and a hydrophilic non-image area accepting dampening water (fountain solution) in the process of printing. Lithographic printing is a printing method utilizing the nature of water and oily ink to repel with each other and comprising rendering the oleophilic image area of the lithographic printing plate to an ink-receptive area and the hydrophilic non-image area thereof to a dampening water-receptive area (ink-unreceptive area), thereby making a difference in adherence of the ink on the surface of the lithographic printing plate, depositing the ink only to the image area, and then transferring the ink to a printing material, for example, paper.

In order to produce the lithographic printing plate, a lithographic printing plate precursor (PS plate) comprising a hydrophilic support having provided thereon an oleophilic photosensitive resin layer (image-recording layer) is used. Specifically, the PS plate is exposed through a mask, for example, a lith film, and then subjected to development processing, for example, with an alkaline developer to remove the unnecessary image-recording layer corresponding to the non-image area by dissolving while leaving the image-recording layer corresponding to the image area, thereby obtaining the lithographic printing plate.

Due to the recent progress in the technical field, nowadays the lithographic printing plate can be obtained by a CTP (computer-to-plate) technology. Specifically, a lithographic printing plate precursor is directly subjected to scanning exposure using laser or laser diode without using a lith film and developed to obtain a lithographic printing plate.

With the progress described above, the issue on the lithographic printing plate precursor has transferred to improvements, for example, in image-forming property corresponding to the CTP technology, printing property or physical property. Also, with the increasing concern about global environment, as another issue on the lithographic printing plate precursor, an environmental problem on waste liquid discharged accompanying the wet treatment, for example, development processing comes to the front.

In response to the environmental problem, simplification of development or plate making or non-processing has been pursued. As one method of simple plate making, a method referred to as an “on-press development” is practiced. Specifically, according to the method after exposure of a lithographic printing plate precursor, the lithographic printing plate precursor is mounted as it is on a printing machine without conducting conventional development and removal of the unnecessary area of image-recording layer is performed at an early stage of printing step.

Also, as a method of simple development, a method referred to as a “gum development” is practiced wherein the removal of the unnecessary area of image-recording layer is performed using not a conventional high alkaline developer but a finisher or gum solution of near-neutral pH.

In the simplification of plate making operation as described above, a system using a lithographic printing plate precursor capable of being handled in a bright room or under a yellow lump and a light source is preferable from the standpoint of workability. Thus, as the light source, a semiconductor laser emitting an infrared ray having a wavelength of 760 to 1,200 or a solid laser, for example, YAG laser, is used. An UV laser is also used.

As the lithographic printing plate precursor capable of undergoing on-press development, for instance, a lithographic printing plate precursor having provided on a hydrophilic support, an image-recording layer (heat-sensitive layer) containing microcapsules having a polymerizable compound encapsulated therein is described in JP-A-2001-277740 (the term “JP-A” as used herein means an “unexamined published Japanese patent application”) and JP-A-2001-277742. A lithographic printing plate precursor having provided on a support, an image-recording layer (photosensitive layer) containing an infrared absorbing agent, a radical polymerization initiator and a polymerizable compound is described in JP-A-2002-287334. A lithographic printing plate precursor capable of undergoing on-press development having provided on a support, an image-recording layer containing a polymerizable compound and a graft polymer having a polyethylene oxide chain in its side chain or a block polymer having a polyethylene oxide block is described in U.S. Patent Publication No. 2003/0064318.

The methods using the polymerization reaction as described above have the feature that since the chemical bond density in the image area is high, the image strength is relatively good in comparison with the image area formed by the thermal fusion of fine polymer particles. However, on-press development property and printing durability are still insufficient.

In order to solve the problem, a lithographic printing plate precursor containing a sulfonate or alkyl sulfuric acid ester salt in its photosensitive layer is described in JP-A-2007-276454 and a lithographic printing plate precursor containing an amino acid or betaine in its protective layer is described in EP-A-1862301. Also, introduction of a specific isocyanuric acid derivative into an image-recording layer is described in JP-A-2008-284817.

### SUMMARY OF THE INVENTION

The techniques described above are still insufficient to achieve compatibility between on-press development property and printing durability in the lithographic printing plate precursor of on-press development type. In particular, it is difficult to well maintain both the on-press development property after preservation of the lithographic printing plate precursor and the printing durability in case of using UV ink. The UV ink is different from conventional ink, does mot contain a solvent and has high viscosity and high tackiness. Also, since it has higher polarity than conventional ink, it tends to attack the image area and ordinarily decreases the printing durability in comparison with conventional ink. Thus, it is a large problem to improve the printing durability (printing durability with UV ink) when UV ink is used.

The present invention has been made under these circumstances and an object of the present invention is to provide a lithographic printing plate precursor of on-press development type which is capable of being subjected to image recording with laser, is prevented from the degradation of on-press development property after preservation of the lithographic printing plate precursor and is excellent in the printing durability with UV ink, and a plate making method using the same.

(1) A lithographic printing plate precursor comprising a support and an image-recording layer a non-image area of which is capable of being removed by supplying printing ink and dampening water and which contains (A) a compound containing two or more isocyanuric acid skeletons each having at least one substituent containing a hydroxy group, (B) an infrared absorbing agent, (C) a radical initiator and (D) a radical polymerizable compound.
(2) The lithographic printing plate precursor as described in (1) above, wherein (A) the compound containing two or more isocyanuric acid skeletons each having at least one substituent containing a hydroxy group is (A1) a compound represented by formula (I) shown below:

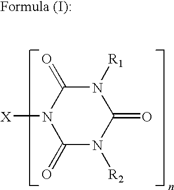

In formula (I), R₁ and R₂ each independently represents a hydrogen atom, an alkyl group, an aryl group or an aralkyl group, provided that at least one of R₁ and R₂ is an alkyl group, aryl group or aralkyl group substituted with a hydroxy group, X represents an n-valent group comprising a combination of atoms selected from a carbon atom, a hydrogen atom, an oxygen atom, a nitrogen atom and a sulfur atom, and n represents an integer of 2 or 10.

(3) The lithographic printing plate precursor as described in (1) above, wherein (A) the compound containing two or more isocyanuric acid skeletons each having at least one substituent containing a hydroxy group is (A2) a polymer having a repeating unit containing an isocyanuric acid skeleton having at least one substituent containing a hydroxy group.
(4) The lithographic printing plate precursor as described in (3) above, wherein the polymer (A2) is (A2a) a vinyl polymer having a repeating unit containing an isocyanuric acid skeleton having at least one substituent containing a hydroxy group in its side chain.
(5) The lithographic printing plate precursor as described in (3) above, wherein the polymer (A2) is (A2b) a polymer which has a repeating unit containing an isocyanuric acid skeleton having at least one substituent containing a hydroxy group in its main chain and is obtained by an addition reaction between a polyfunctional carboxylic acid and a polyfunctional epoxy compound.
(6) The lithographic printing plate precursor as described in any one of (1) to (5) above, wherein the image-recording layer further contains (E) a hydrophobilizing precursor.
(7) The lithographic printing plate precursor as described in (6) above, wherein (E) the hydrophobilizing precursor is a microcapsule and/or a microgel.
(8) The lithographic printing plate precursor as described in anyone of (1) to (7) above, wherein (D) the radical polymerizable compound is (D1) a compound having an isocyanuric acid skeleton.
(9) The lithographic printing plate precursor as described in any one of (1) to (8) above, which has a protective layer on the image-recording layer.
(10) The lithographic printing plate precursor as described in (9) above, wherein the protective layer contains an inorganic stratiform compound.
(11) A plate making method comprising a step of exposing imagewise the lithographic printing plate precursor as described in any one of (1) to (10) above and a step of removing an unexposed area of the image-recording layer by supplying oily ink and an aqueous component on a printing machine without applying any development processing to the exposed lithographic printing plate precursor.

The inventor has found that a lithographic printing plate precursor excellent in on-press development property is obtained by adding a specific isocyanuric acid derivative (compound containing at least two isocyanuric acid skeletons in its molecule and having as a substituent, at least one group having a hydroxy group per the isocyanuric acid skeleton and hereinafter, also referred to as component (A)) to an image-recording layer. It has also be surprisingly found that the degradation of on-press development property after preservation of the lithographic printing plate precursor is prevented and the printing durability with UV ink is improved by using the component (A) according to the invention to complete the invention.

The factors for fulfilling the functions of the component (A) according to the invention are believed to be as follows. Specifically, the isocyanuric acid skeleton and hydroxy group in the component (A) according to the invention act as hydrophilic parts to contribute improvement in the on-press development property. Also, since the component (A) according to the invention has connected isocyanuric acid skeletons, the diffusibility thereof in a coated layer is reduced and fluctuation of the on-press development property due to the preservation is small in comparison with a compound having only one isocyanuric acid skeleton. Further, since the isocyanuric acid derivative has high planarity and tends to cause self-assembly, the components (A) according to the invention form a pseudo-crosslinked state to increase resistance to UV ink, thereby improving the printing durability.

According to the present invention, a lithographic printing plate precursor of on-press development type which is prevented from the degradation of on-press development property after preservation of the lithographic printing plate precursor and is excellent in the printing durability with UV ink, and a plate making method using the lithographic printing plate precursor can be provided.

### DETAILED DESCRIPTION OF THE INVENTION

### Lithographic Printing Plate Precursor

The lithographic printing plate precursor according to the invention comprises a support and an image-recording layer. The lithographic printing plate precursor may also have a protective layer on the image-recording layer and an undercoat layer between the support and the image-recording layer according to the circumstances.

The constituting element, component and the like of the lithographic printing plate precursor according to the invention will be described below.

### (Image-Recording Layer)

The image-recording layer for use in the invention is characterized by containing (A) a compound containing two or more isocyanuric acid skeletons each having at least one substituent containing a hydroxy group, (B) an infrared absorbing agent, (C) a radical initiator and (D) a radical polymerizable compound.

Also, the image-recording layer for use in the invention is an image-recording layer a non-image area of which is capable of being removed by supplying printing ink and dampening water, that is, an image-recording layer capable of undergoing on-press development. The image-recording layer may further contain (E) a hydrophobilizing precursor.

Each of the components contained in the image-recording layer will be described in order below.

<(A) Compound Containing Two or More Isocyanuric Acid Skeletons Each Having at Least One Substituent Containing a Hydroxy Group [Hereinafter, also Referred to as Component (A)]>

The component (A) according to the invention may be any compound containing at least two isocyanuric acid skeletons in its molecule and having as a substituent, at least one group having a hydroxy group per the isocyanuric acid skeleton and is particularly preferably a compound containing at least two isocyanuric acid skeletons each having two or more substituents containing a hydroxy group.

Of the components (A), (A1) a compound represented by formula (I) shown below and (A2) a polymer having a repeating unit containing an isocyanuric acid skeleton having at least one substituent containing a hydroxy group are preferable.

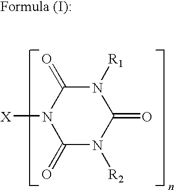

In formula (I), R₁ and R₂ each independently represents a hydrogen atom, an alkyl group which may have a substituent, an aryl group which may have a substituent or an aralkyl group which may have a substituent, provided that at least one of R₁ and R₂ is an alkyl group substituted with a hydroxy group, an aryl group substituted with a hydroxy group or an aralkyl group substituted with a hydroxy group. Between a carbon-carbon bond in the alkyl group or an alkylene group of the aralkyl group, —O—, —S—, —N(Rₓ)—, —CO—, —SO₂— or a group formed by combination of these groups may be present. Rₓ represents a hydrogen atom, an alkyl group, an aryl group or an aralkyl group.

The alkyl group represented by R₁ or R₂ may be any of straight-chain, branched, monocyclic and polycyclic forms and a total number of carbon atoms included therein is preferably 40 or less, more preferably 30 or less and most preferably 20 or less. Specific examples thereof include a methyl group, an ethyl group, a n-propyl group, an isopropyl group, a n-butyl group, a sec-butyl group, a tert-butyl group, a n-pentyl group, a n-hexyl group, a n-decyl group and a n-dodecyl group. The alkyl group may have a substituent described below.

As for the aryl group represented by R₁ or R₂, a total number of carbon atoms included therein is preferably 30 or less, more preferably 20 or less and most preferably 15 or less. Specific examples thereof include a phenyl group, a naphthyl group and an anthryl group. The aryl group may have a substituent described below.

As for the aralkyl group represented by R₁ or R₂, a total number of carbon atoms included therein is preferably 30 or less, more preferably 20 or less and most preferably 15 or less. Specific examples thereof include a benzyl group, a 2-phenylethyl group, a 3-phenylpropyl group, a naphthylmethyl group, a 2-naphtylethyl group and a 3-naphthylpropyl group. The aralkyl group may have a substituent described below.

The substituent which the alkyl group, aryl group or aralkyl group may have includes, for example, a halogen atom, a cyano group, a hydroxy group, an alkoxy group, a mercapto group, an alkylthio group, a carboxyl group, an ester group and an amido group.

At least one of R₁ and R₂ is an alkyl group substituted with a hydroxy group, an aryl group substituted with a hydroxy group or an aralkyl group substituted with a hydroxy group. Specific examples of the alkyl group, aryl group and aralkyl group include those described above. Among them, an alkyl group substituted with a hydroxy group is preferable. It is more preferable that each of R₁ and R₂ is an alkyl group substituted with a hydroxy group. As for the alkyl group, a number of carbon atoms included is preferably 20 or less, more preferably 15 or less and most preferably 10 or less. Between a carbon-carbon bond in the alkyl group, —O—, —S—, —N(Rₓ)—, —CO—, —SO₂— or a group formed by combination of these groups may be present. Among them, —O—, —S—, —O—CO—, —N(Rₓ)—CO—, —O—CO—N(Rₓ)— and the like are preferable. Rₓ has the same meaning as Rₓ defined above.

X represents an n-valent group comprising a combination of atoms selected from a carbon atom, a hydrogen atom, an oxygen atom, a nitrogen atom and a sulfur atom. Specific examples of the n-valent group include a hydrocarbon group, —O—, —S—, —N(R_{y})—, —CO—, —SO₂— and a group formed by combination of these groups. R_{y} represents a single bond or any one of those defined for R. The hydrocarbon group may be any of aliphatic group and aromatic ring and may have any of chainlike, monocyclic and polycyclic forms. Between a carbon-carbon bond in the hydrocarbon group, —O—, —S—, —N(Rₓ)—, —CO—, —SO₂— or a group formed by combination of these groups may be present. Rₓ has the same meaning as Rₓ defined above.

n represents an integer of 2 or 10 and is preferably an integer of 2 to 8, more preferably an integer of 2 to 6, and most preferably an integer of 2 to 4.

The n-valent group represented by X is preferably a chainlike hydrocarbon group, a cyclic hydrocarbon group, an aromatic hydrocarbon group, —O—, —S—, —N(R_{y})—, —CO—, —SO₂— or a group formed by combination of these groups, more preferably a straight-chain hydrocarbon group having 10 or less carbon atoms, a 6-membered or less cyclic hydrocarbon group, a 10-membered or less aromatic hydrocarbon group, —O—, —S—, —CO—O—, —N(R_{y})—CO—, —N(R_{y})—CO—O—, —SO₂— or a group formed by combination of these groups, and most preferably a straight-chain hydrocarbon group having 10 or less carbon atoms, a cyclopentane or cyclohexane residue, a benzene residue, —O—, —CO—O—, —N(R_{y})—CO—, —N(R_{y})—CO—O— or a group formed by combination of these groups.

Specific examples of the compound represented by formula (I) are set forth below.

TABLE 1
Compounds A-1 to A-22

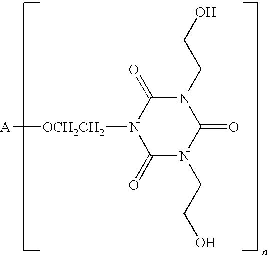

| Compound | n | A |
|---|---|---|
| A-1 | 2 | —(CH₂)₂— |
| A-2 | 2 | —(CH₂)₄— |
| A-3 | 2 | —(CH₂)₆— |
| A-4 | 2 | —CH₂CH₂O—CH₂CH₂— |
| A-5 | 2 | —(CH₂CH₂O)₂-CH₂CH₂— |
| A-6 | 2 | —CO—(CH₂)₂—CO— |
| A-7 | 2 | —CO—(CH₂)₅—CO— |
| A-8 | 2 | —CO—CH₂OCH₂—CO— |
| A-9 | 2 | —CONH—(CH₂)₄—NHCO— |
| A-10 | 2 | —CONH—(CH₂)₆—NHCO— |
| A-11 | 2 | —CONH—(CH₂CH₂O)₂—CH₂CH₂—NHCO— |
| A-12 | 2 | 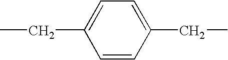 |
| A-13 | 2 | 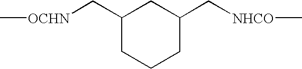 |
| A-14 | 2 | 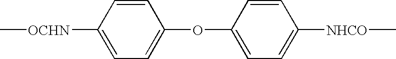 |
| A-15 | 3 | 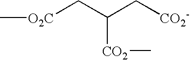 |
| A-16 | 3 | 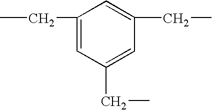 |
| A-17 | 3 | 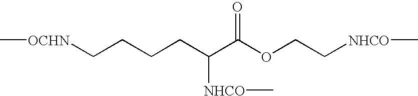 |
| A-18 | 3 | 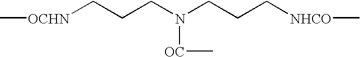 |
| A-19 | 4 | 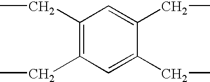 |
| A-20 | 4 | 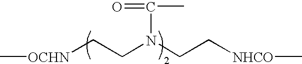 |
| A-21 | 5 | 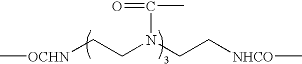 |
| A-22 | 6 | 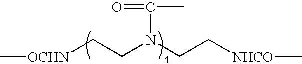 |

TABLE 2
Compounds A-31 to A-38

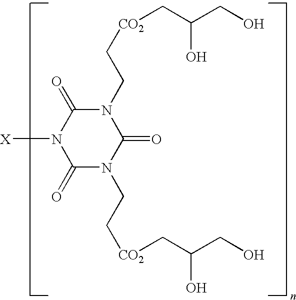

| Compound | n | X |
|---|---|---|
| A-31 | 2 | —(CH₂)₂— |
| A-32 | 2 | —(CH₂)₄— |
| A-33 | 2 | —(CH₂)₆— |
| A-34 | 2 | —CH₂CH₂O—CH₂CH₂— |
| A-35 | 2 | —(CH₂CH₂O)₂-CH₂CH₂— |
| A-36 | 2 | 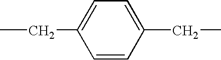 |
| A-37 | 3 | 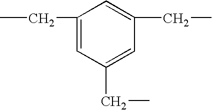 |
| A-38 | 4 | 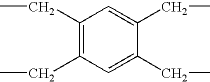 |

### <(A2) Polymer Having a Repeating Unit Containing an Isocyanuric Acid Skeleton Having at Least One Substituent Containing a Hydroxy Group [Component (A2)]>

The polymer means a compound which is obtained by a polymerization reaction of one or more monomers and has a weight average molecular weight (Mw) of 1,000 or more. The upper limit of the Mw is preferably 100,000, more preferably 60,000, and most preferably 40,000.

The component (A2) includes a polymer having the isocyanuric acid skeleton introduced into its side chain and a polymer having the isocyanuric acid skeleton introduced into its main chain. The component (A2) is preferably (A2a) a vinyl polymer having a repeating unit containing an isocyanuric acid skeleton having at least one substituent containing a hydroxy group in its side chain or (A2b) a polymer which has a repeating unit containing an isocyanuric acid skeleton having at least one substituent containing a hydroxy group in its main chain and is obtained by an addition reaction between a polyfunctional carboxylic acid and a polyfunctional epoxy compound.

<(A2a) Vinyl Polymer Having a Repeating Unit Containing an Isocyanuric Acid Skeleton Having at Least One Substituent Containing a Hydroxy Group in its Side Chain [Hereinafter, also Referred to as Component (A2a)]>

The component (A2a) preferably includes a polymer having two or more repeating units represented by formula (II) shown below.

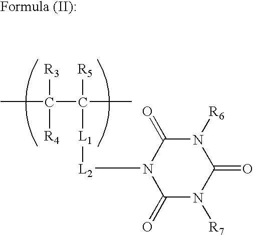

In formula (II), R₃ and R₄ each independently represents a hydrogen atom, a halogen atom, an alkyl group or an aryl group. R₅ represents a hydrogen atom, a halogen atom or an alkyl group.

R₆ and R₂ have the same meanings as R₁ and R₂ in formula (I) above, respectively, and at least one of R₆ and R₂ represents an alkyl group, aryl group or aralkyl group substituted with a hydroxy group.

L₁ represents —CO—O—, —CO—N(Rₓ)— or a phenylene group. L₂ represents an alkylene group, —O—, —S—, —N(Rₓ)—, —CO—, —SO₂— or a group formed by combination of these groups. Rₓ has the same meaning as Rₓ in formula (I) above.

The component (A2a) is obtained by copolymerization of a monomer corresponding to the repeating unit represented by formula (II) and, if desired, other known copolymerizable monomer. In case of the copolymerization, the content of the repeating unit represented by formula (II) is ordinarily 50% by mole or more, preferably 60% by mole or more, and more preferably 70% by mole or more. The known copolymerizable monomer includes, for example, various (meth) acrylate monomers, (meth) acrylamide monomers and styrene monomers.

It is preferred that the other copolymerizable monomer does not contain an acidic group, for example, a carboxylic acid, a sulfonic acid or a phosphoric acid or that when it contains an acidic group, the acidic group forms the neutralized salt thereof. Also, the other copolymerizable monomer is preferably hydrophilic. Specifically, the copolymerizable monomer containing a hydroxy group, a polyethylene oxy group, a polypropylene oxy group, an amido group or the salt of acid group described above is preferable.

Specific examples of the repeating unit represented by formula (II) are set forth below, but the invention should not be construed as being limited thereto.

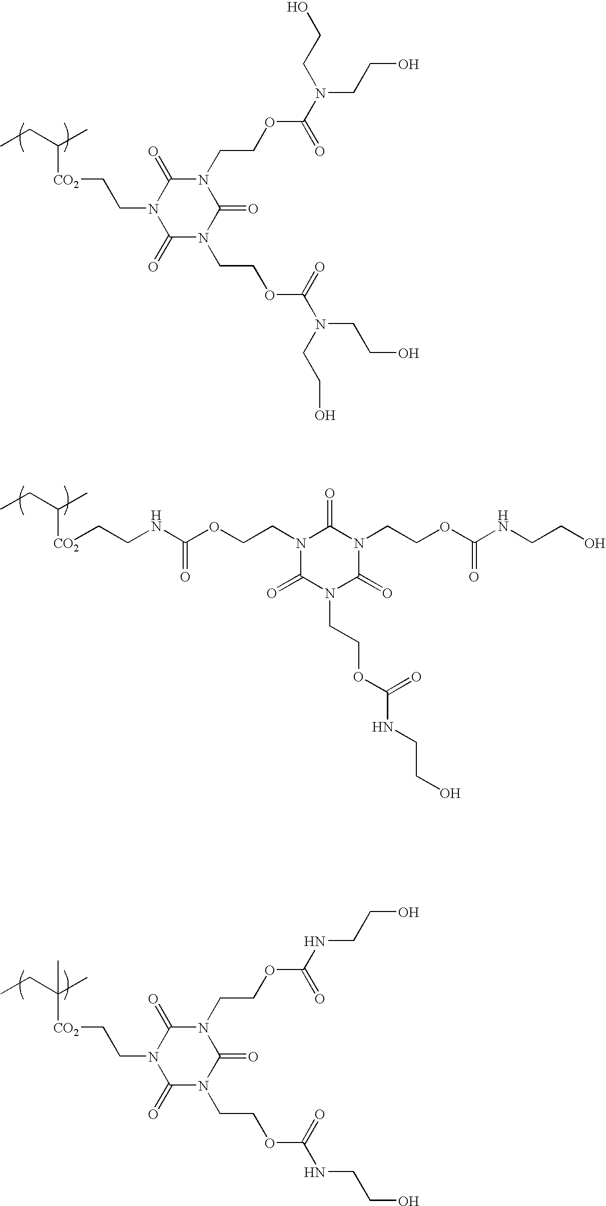

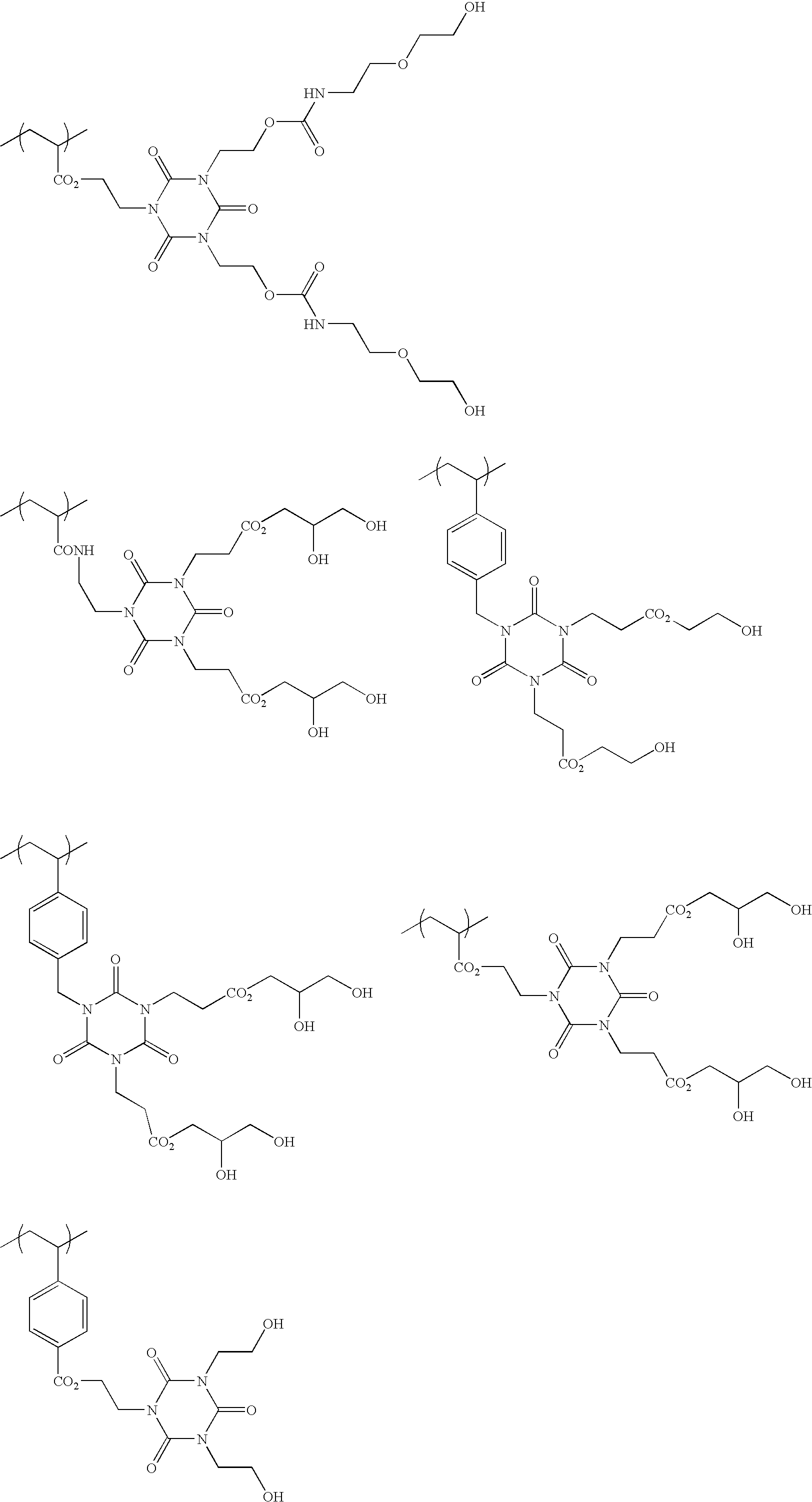

<(A2b) Polymer which has a Repeating Unit Containing an Isocyanuric Acid Skeleton Having at Least One Substituent Containing a Hydroxy Group in its Main Chain and is Obtained by an Addition Reaction Between a Polyfunctional Carboxylic Acid and a Polyfunctional Epoxy Compound [Hereinafter, also Referred to as Component (A2b)]>

Specific examples of the component (A2b) include a polymer obtained by an addition reaction between a polyfunctional carboxylic acid containing the isocyanuric acid skeleton and a polyfunctional epoxy compound and a polymer obtained by an addition reaction between a polyfunctional epoxy compound containing the isocyanuric acid skeleton and a polyfunctional carboxylic acid. A number of the functional groups in the polyfunctional carboxylic acid or the polyfunctional epoxy compound is preferably 2 or 3, and most preferably 2. In the addition reaction, known synthesis methods using various kinds of catalysts may be utilized. For instance, a method of using an acid catalyst, for example, an inorganic acid or an organic acid, a method of using a tetraalkylammonium salt, a method of using a betaine and a method of using an organic phosphorous (for example, trialkylphosphine or triarylphosphine) are exemplified.

When the numbers of the functional groups in the polyfunctional carboxylic acid and the polyfunctional epoxy compound are 2 respectively, a polymer obtained by the addition reaction has a linear structure. In such a case, a molar ratio of the carboxylic acid and the epoxy group at the addition reaction is ordinarily from 45/55 to 55/45, preferably from 47/53 to 53/47, and more preferably from 48/52 to 52/48.

When the number of the functional groups in the polyfunctional carboxylic acid and/or the number of the functional groups in the polyfunctional epoxy compound is 3 or more, a polymer obtained by the addition reaction has a crosslinked structure. In such a case, attention is required because when the crosslinked points are too much, the polymer becomes insoluble in a solvent.

When the number of the functional groups in the polyfunctional carboxylic acid is 2 and the number of the functional groups in the polyfunctional epoxy compound is 3, a molar ratio of the carboxylic acid and the epoxy group at the addition reaction is ordinarily from 2.5/1 to 1.5/1, preferably from 2.0/1 to 1.5/1, and more preferably from 1.8/1 to 1.5/1.

When the number of the functional groups in the polyfunctional carboxylic acid is 3 and the number of the functional groups in the polyfunctional epoxy compound is 2, a molar ratio of the carboxylic acid and the epoxy group at the addition reaction is ordinarily from 1/2.5 to 1/1.5, preferably from 1/2.0 to 1/1.5, and more preferably from 1/1.8 to 1/1.5.

After the addition reaction, in order to remove the remaining carboxylic acid, a monofunctional epoxy compound may be added.

A preferable weight average molecular weight (Mw) of the component (A2b) is same as that described with respect to the component (A2).

Specific examples of the component (A2b) include products obtained by the reaction shown below.

TABLE 3
Compounds A2b-1 to A2-b-9

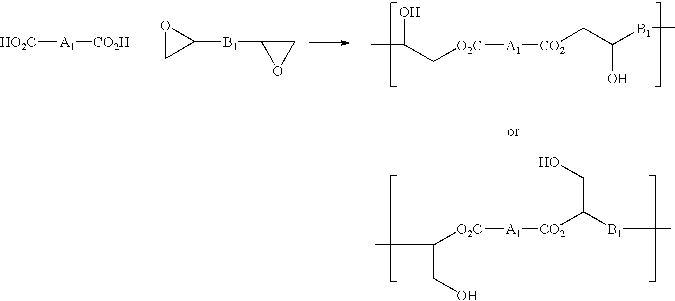

| Compound | HO₂C—A₁—CO₂H | 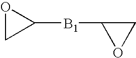 |
|---|---|---|
| A2b-1 | 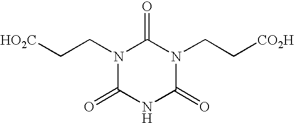 | 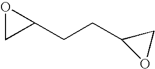 |
| A2b-2 | 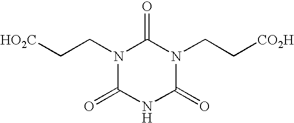 | 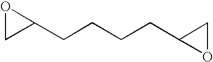 |
| A2b-3 | 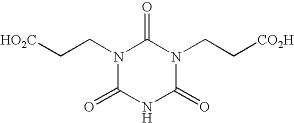 | 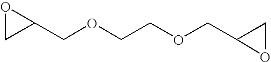 |
| A2b-4 | 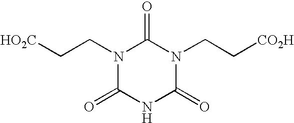 | 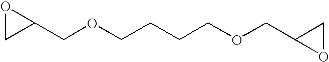 |
| A2b-5 | 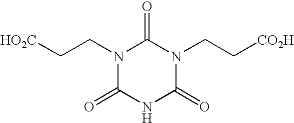 | 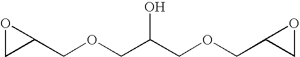 |
| A2b-6 | 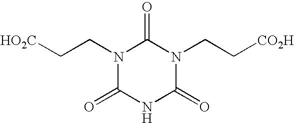 | 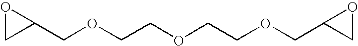 |
| A2b-7 | 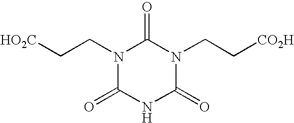 | 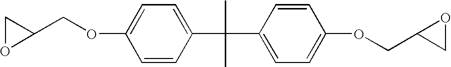 |
| A2b-8 | 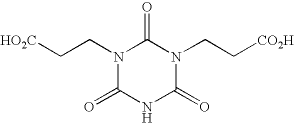 | 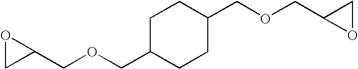 |
| A2b-9 | 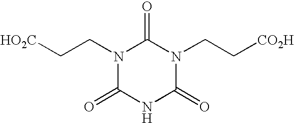 | 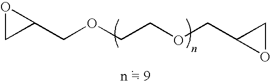 |

Specific examples of the component (A2b) also include products obtained by the reaction shown below.

TABLE 4
Compounds A2b-11 to A2b-13

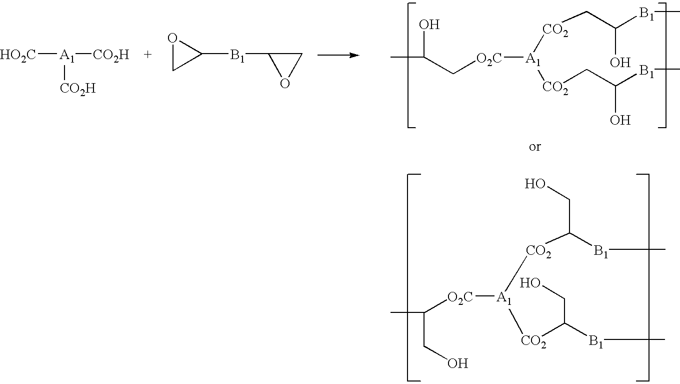

| Compound | 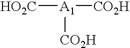 | 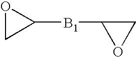 |
|---|---|---|
| A2b-11 | 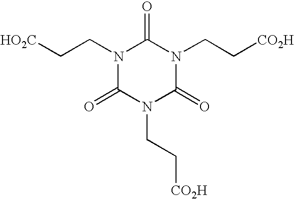 | 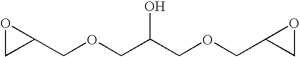 |
| A2b-12 | 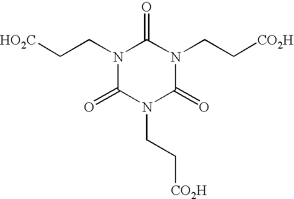 | 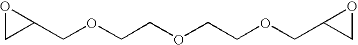 |
| A2b-13 | 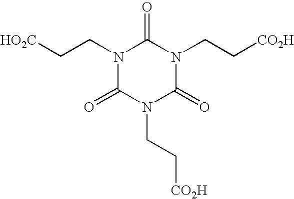 | 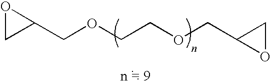 |

Specific examples of the component (A2b) also include products obtained by the reaction shown below.

TABLE 5
Compounds A2b-21 to A2b-28

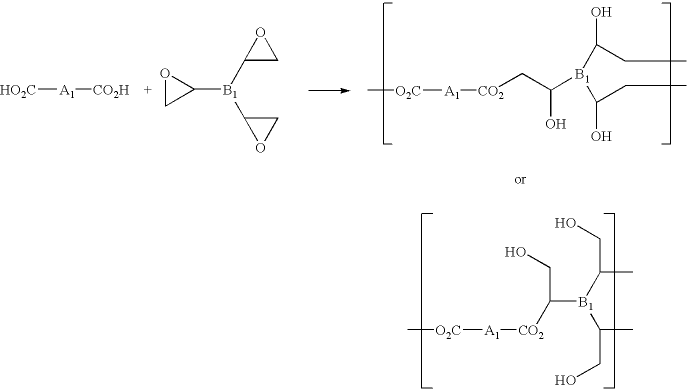

| Compound | HO₂C—A₁—CO₂H | 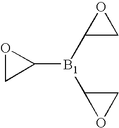 |
|---|---|---|
| A2b-21 | 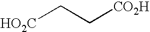 | 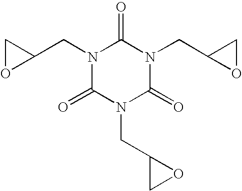 |
| A2b-22 | 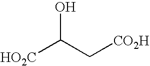 | 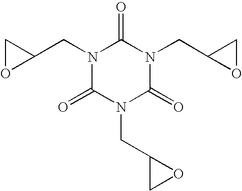 |
| A2b-23 | 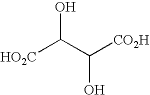 | 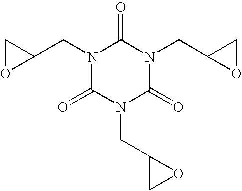 |
| A2b-24 | 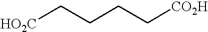 | 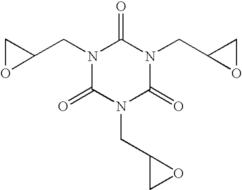 |
| A2b-25 | 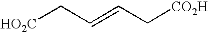 | 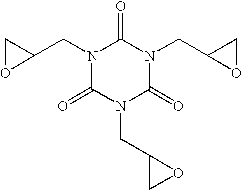 |
| A2b-26 | 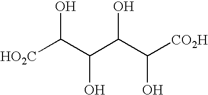 | 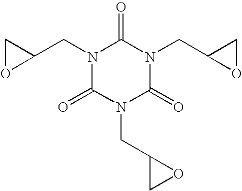 |
| A2b-27 | 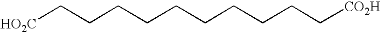 | 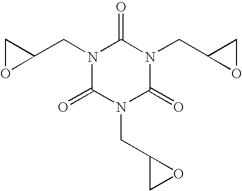 |
| A2b-28 | 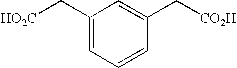 | 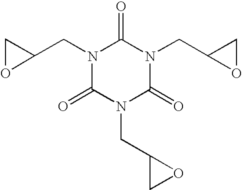 |

The content of the component (A) in the image-recording layer according to the invention is preferably from 0.5 to 60% by weight, more preferably from 2 to 30% by weight, base on the total solid content of the image-recording layer.

### <(B) Infrared Absorbing Agent>

The infrared absorbing agent has a function of converting the infrared ray absorbed to heat and a function of being excited by the infrared ray to perform electron transfer and/or energy transfer to a radical initiator described hereinafter. The infrared absorbing agent for use in the invention is a dye or pigment having an absorption maximum in a wavelength range of 760 to 1,200 nm.

As the infrared absorbing agent, compounds described in Paragraph Nos. [0058] to [0087] of JP-A-2008-195018 are used.

Of the infrared absorbing dyes, cyanine dyes, squarylium dyes, pyrylium dyes and nickel thiolate complexes are particularly preferred. As the particularly preferable example of the dye, a cyanine dye represented by formula (a) shown below is exemplified.

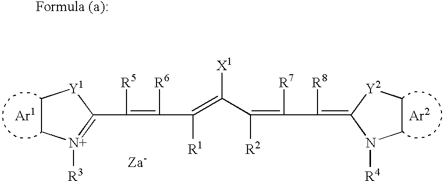

In formula (a), X¹ represents a hydrogen atom, a halogen atom, —N(R⁹)(R¹⁰), X²-L¹ or a group shown below. R⁹ and R¹⁰, which may be the same or different, each represents an aromatic hydrocarbon group having from 6 to 10 carbon atoms, which may have a substituent, an alkyl group having from 1 to 8 carbon atoms, which may have a substituent or a hydrogen atom, or R⁹ and R¹⁰ may be combined with each other to form a ring. Among them, a phenyl group is preferable. X² represents an oxygen atom or a sulfur atom, L¹ represents a hydrocarbon group having from 1 to 12 carbon atoms, an aromatic ring group containing a hetero atom or a hydrocarbon group having from 1 to 12 carbon atoms and containing a hetero atom. The hetero atom used herein indicates a nitrogen atom, a sulfur atom, an oxygen atom, a halogen atom and a selenium atom. In the group shown below, Xa⁻ has the same meaning as Za⁻ defined hereinafter, and R^{a} represents a hydrogen atom or a substituent selected from an alkyl group, an aryl group, a substituted or unsubstituted amino group and a halogen atom.

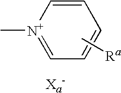

R¹ and R² each independently represents a hydrocarbon group having from 1 to 12 carbon atoms. In view of the preservation stability of a coating solution for image-recording layer, it is preferred that and R² each represents a hydrocarbon group having two or more carbon atoms. It is also preferred that and R² are combined with each other to form a 5-membered or 6-membered ring.

Ar¹ and Ar², which may be the same or different, each represents an aromatic hydrocarbon group which may have a substituent. Preferable examples of the aromatic hydrocarbon group include a benzene ring group and a naphthalene ring group. Also, preferable examples of the substituent include a hydrocarbon group having 12 or less carbon atoms, a halogen atom and an alkoxy group having 12 or less carbon atoms. Y¹ and Y², which may be the same or different, each represents a sulfur atom or a dialkylmethylene group having 12 or less carbon atoms. R³ and R⁴, which may be the same or different, each represents a hydrocarbon group having 20 or less carbon atoms, which may have a substituent. Preferable examples of the substituent include an alkoxy group having 12 or less carbon atoms, a carboxyl group and a sulfo group. R⁵, R⁶, R⁷ and R⁸, which may be the same or different, each represents a hydrogen atom or a hydrocarbon group having 12 or less carbon atoms. In view of the availability of raw materials, a hydrogen atom is preferred. Za⁻ represents a counter anion. However, Za⁻ is not necessary when the cyanine dye represented by formula (a) has an anionic substituent in the structure thereof and neutralization of charge is not needed. In view of the preservation stability of a coating solution for image-recording layer, preferable examples of the counter ion for Za⁻ include a halide ion, a perchlorate ion, a tetrafluoroborate ion, a hexafluorophosphate ion and a sulfonate ion, and particularly preferable examples thereof include a perchlorate ion, a hexafluorophosphate ion and an arylsulfonate ion.

Specific examples of the cyanine dye represented by formula (a), which can be preferably used in the invention, include those described in Paragraph Nos. [0017] to [0019] of JP-A-2001-133969, Paragraph Nos. [0012] to [0021] of JP-A-2002-23360 and Paragraph Nos. [0012] to [0037] of JP-A-2002-40638.

The infrared absorbing agents may be used individually or in combination of two or more thereof. In case of using in combination, a pigment may be used. As the pigment, compounds described in Paragraph Nos. [0072] to [0076] of JP-A-2008-195018 are preferably used.

The content of the infrared absorbing agent in the image-recording layer according to the invention is preferably from 0.1 to 10.0% by weight, more preferably from 0.5 to 5.0% by weight, based on the total solid content of the image-recording layer.

### <(C) Radical Initiator>

The radical initiator (C) for use in the invention is a compound which initiates or accelerates polymerization of a radical polymerizable compound (D). As the radical generator for use in the invention, a radical polymerization initiator is preferable and, for example, known thermal polymerization initiators, compounds containing a bond having small bond dissociation energy and photopolymerization initiators are used.

The radical generators in the invention include, for example, (a) organic halides, (b) carbonyl compounds, (c) azo compounds, (d) organic peroxides, (e) metallocene compounds, (f) azido compounds, (g) hexaarylbiimidazole compounds, (h) organic borate compounds, (i) disulfone compounds, (j) oxime ester compounds and (k) onium salt compounds.

Specific examples of the radical generators (a) to (k) described above include compounds described in JP-A-2008-195018.

Of the radical generators described above, an onium salt, especially, an iodonium salt, a sulfonium salt or an azinium salt is preferable. Specific examples of these compounds are set forth below, but the invention should not be construed as being limited thereto.

Of the iodonium salts, a diphenyliodonium salt is preferable, a diphenyliodonium salt substituted with an electron donating group, for example, an alkyl group or an alkoxy group is more preferable, and an asymmetric diphenyliodonium salt is still more preferable. Examples of the iodonium salt include diphenyliodonium hexafluorophosphate, 4-methoxyphenyl-4-(2-methylpropyl)phenyliodonium hexafluorophosphate, 4-(2-methylpropyl)phenyl-p-tolyliodonium hexafluorophosphate, 4-hexyloxyphenyl-2,4,6-trimethoxyphenyliodonium hexafluorophosphate, 4-hexyloxyphenyl-2,4-diethoxyphenyliodoniumtetraphenylborate, 4-octyloxyphenyl-2,4,6-trimethoxyphenyliodonium 1-perfluorobutanesulfonate, 4-octyloxyphenyl-2,4,6-trimethoxyphenyliodonium hexafluorophosphate and bis(4-tert-butylphenyl)iodonium tetraphenylborate.

Examples of the sulfonium salt include triphenylsulfonium hexafluorophosphate, triphenylsulfonium benzoylformate, bis(4-chlorophenyl)phenylsulfonium benzoylformate, bis(4-chlorophenyl)-4-methylphenylsulfonium tetrafluoroborate and tris(4-chlorophenyl)sulfonium 3,5-bis(methoxycarbonyl)benzenesulfonate.

Examples of the azinium salt include 1-cyclohexylmethyloxypyridinium hexafluorophosphate, 1-cyclohexyloxy-4-phenylpyridinium hexafluorophosphate, 1-ethoxy-4-phenylpyridinium hexafluorophosphate, 1-(2-ethylhexyloxy)-4-phenylpyridinium hexafluorophosphate, 4-chloro-1-cyclohexylmethyloxypyridinium hexafluorophosphate, 1-ethoxy-4-cyanopyridinium hexafluorophosphate, 3,4-dichloro-1-(2-ethylhexyloxy)pyridinium hexafluorophosphate, 1-benzyloxy-4-phenylpyridinium hexafluorophosphate, 1-phenethyloxy-4-phenylpyridinium hexafluorophosphate, 1-(2-ethylhexyloxy)-4-phenylpyridinium p-toluenesulfonate, 1-(2-ethylhexyloxy)-4-phenylpyridinium perfluorobutanesulfonate, 1-(2-ethylhexyloxy)-4-phenylpyridinium bromide and 1-(2-ethylhexyloxy)-4-phenylpyridinium tetrafluoroborate.

The radical initiator can be added to the image-recording layer preferably in an amount from 0.1 to 50% by weight, more preferably from 0.5 to 30% by weight, particularly preferably from 0.8 to 20% by weight, based on the total solid content constituting the image-recording layer. In the range described above, good sensitivity and good stain resistance in the non-image area at the time of printing are obtained.

### <(D) Radical Polymerizable Compound>

The radical polymerizable compound (D) for use in the invention is an addition-polymerizable compound having at least one ethylenically unsaturated double bond, and it is preferably selected from compounds having at least one, preferably two or more, terminal ethylenically unsaturated double bonds. Such compounds are widely known in the field of art and they can be used in the invention without any particular limitation. The compound has a chemical form, for example, a monomer, a prepolymer, specifically, a dimer, a trimer or an oligomer, or a (co)polymer thereof, or a mixture thereof.

Specific examples of the radical polymerizable compound include compounds described in Paragraph Nos. [0089] to [0098] of JP-A-2008-195018. Among them, esters of aliphatic polyhydric alcohol compound with an unsaturated carboxylic acid (for example, acrylic acid, methacrylic acid, itaconic acid, crotonic acid, isocrotonic acid or maleic acid) are preferably exemplified. Other preferable radical polymerizable compound includes polymerizable compounds containing an isocyanuric acid structure described in JP-A-2005-329708.

Among them, a polymerizable compound having an isocyanuric acid skeleton is preferable, and isocyanuric acid ethylene oxide-modified acrylates, for example, tris(acryloyloxyethyl) isocyanurate or bis(acryloyloxyethyl)hydroxyethyl isocyanurate are particularly preferable.

The radical polymerizable compound (D) is preferably used in an amount from 5 to 80% by weight, more preferably from 25 to 75% by weight, based on the total solid content of the image-recording layer.

### <(E) Hydrophobilizing Precursor>

According to the invention, a hydrophobilizing precursor can be used in order to improve the on-press development property. The hydrophobilizing precursor for use in the invention is a fine particle capable of converting the image-recording layer to be hydrophobic when heat is applied. The fine particle is preferably at least one fine particle selected from hydrophobic thermoplastic polymer fine particle, thermo-reactive polymer fine particle, microcapsule having a hydrophobic compound encapsulated and microgel (crosslinked polymer fine particle). Among them, polymer fine particle having a polymerizable group and microgel are preferable.

As the hydrophobic thermoplastic polymer fine particle, hydrophobic thermoplastic polymer fine particles described, for example, in Research Disclosure, No. 33303, January (1992), JP-A-9-123387, JP-A-9-131850, JP-A-9-171249, JP-A-9-171250 and European Patent 931,647 are preferably exemplified.

Specific examples of the polymer constituting the polymer fine particle include a homopolymer or copolymer of a monomer, for example, ethylene, styrene, vinyl chloride, methyl acrylate, ethyl acrylate, methyl methacrylate, ethyl methacrylate, vinylidene chloride, acrylonitrile, vinyl carbazole or an acrylate or methacrylate having a polyalkylene structure and a mixture thereof. Among them, polystyrene and polymethyl methacrylate are more preferable.

The average particle size of the hydrophobic thermoplastic polymer fine particle for use in the invention is preferably from 0.01 to 2.0 μm.

The thermo-reactive polymer fine particle for use in the invention includes a polymer fine particle having a thermo-reactive group and forms a hydrophobilized region by crosslinkage due to thermal reaction and change in the functional group involved therein.

As the thermo-reactive group of the polymer fine particle having a thermo-reactive group for use in the invention, a functional group performing any reaction can be used as long as a chemical bond is formed. For instance, an ethylenically unsaturated group (for example, an acryloyl group, a methacryloyl group, a vinyl group or an allyl group) performing a radical polymerization reaction, a cationic polymerizable group (for example, a vinyl group or a vinyloxy group), an isocyanate group performing an addition reaction or a blocked form thereof, an epoxy group, a vinyloxy group and a functional group having an active hydrogen atom (for example, an amino group, a hydroxy group or a carboxyl group) as the reaction partner thereof, a carboxyl group performing a condensation reaction and a hydroxyl group or an amino group as the reaction partner thereof, and an acid anhydride performing a ring opening addition reaction and an amino group or a hydroxyl group as the reaction partner thereof are preferably exemplified.

As the microcapsule for use in the invention, microcapsule having all or part of the constituting components of the image-recording layer encapsulated as described, for example, in JP-A-2001-277740 and JP-A-2001-277742 is exemplified. The constituting components of the image-recording layer may be present outside the microcapsules. It is a more preferable embodiment of the image-recording layer containing microcapsules that hydrophobic constituting components are encapsulated in microcapsules and hydrophilic components are present outside the microcapsules.

The image-recording layer according to the invention is an embodiment containing a crosslinked resin particle, that is, a microgel. The microgel can contain a part of the constituting components of the image-recording layer inside and/or on the surface thereof. Particularly, an embodiment of a reactive microgel containing the radical polymerizable compound (D) on the surface thereof is preferable in view of the image-forming sensitivity and printing durability.

As a method of microencapsulation or microgelation of the constituting components of the image-recording layer, known methods can be used.

The average particle size of the microcapsule or microgel is preferably from 0.01 to 3.0 μm, more preferably from 0.05 to 2.0 μm, particularly preferably from 0.10 to 1.0 μm. In the range described above, good resolution and good time-lapse stability can be achieved.

The content of the hydrophobilizing precursor is preferably in a range of 5 to 90% by weight in terms of solid content concentration of the image-recording layer.

### <(F) Other Components>

The image-recording layer according to the invention may further contain other components, if desired.

### (1) Binder Polymer

In the image-recording layer according to the invention, a binder polymer can be used for the purpose of improving film strength of the image-recording layer. The binder polymer which can be used in the invention can be selected from those heretofore known without restriction, and polymers having a film-forming property are preferable. Among them, acrylic resins, polyvinyl acetal resins and polyurethane resins are preferable.

As the binder polymer preferable for the invention, a polymer having a crosslinkable functional group for improving film strength of the image area in its main chain or side chain, preferably in its side chain, as described in JP-A-2008-195018 is exemplified. Due to the crosslinkable functional group, crosslinkage is formed between the polymer molecules to facilitate curing.

As the crosslinkable functional group, an ethylenically unsaturated group, for example, a (meth)acryl group, a vinyl group or an allyl group or an epoxy group is preferable. The crosslinkable functional group can be introduced into the polymer by a polymer reaction or copolymerization. For instance, a reaction between an acrylic polymer or polyurethane having a carboxyl group in its side chain and glycidyl methacrylate or a reaction between a polymer having an epoxy group and a carboxylic acid containing an ethylenically unsaturated group, for example, methacrylic acid can be utilized.

The content of the crosslinkable group in the binder polymer is preferably from 0.1 to 10.0 mmol, more preferably from 1.0 to 7.0 mmol, most preferably from 2.0 to 5.5 mmol, based on 1 g of the binder polymer.

It is also preferred that the binder polymer for use in the invention further contains a hydrophilic group. The hydrophilic group contributes to impart the on-press development property to the image-recording layer. In particular, coexistence of the crosslinkable group and the hydrophilic group makes it possible to maintain good balance between printing durability and developing property.

The hydrophilic group includes, for example, a hydroxy group, a carboxyl group, an alkylene oxide structure, an amino group, an ammonium group, an amido group, a sulfo group and a phosphoric acid group. Among them, an alkylene oxide structure containing from 1 to 9 alkylene oxide units having 2 or 3 carbon atoms is preferable. In order to introduce a hydrophilic group into the binder polymer, a monomer having the hydrophilic group is copolymerized.

In order to control the ink-receptive property, an oleophilic group, for example, an alkyl group, an aryl group, an aralkyl group or an alkenyl group may be introduced into the binder polymer according to the invention. Specifically, an oleophilic group-containing monomer, for example, an alkyl methacrylate is copolymerized.

Specific examples of the binder polymer for use in the invention are set forth below, but the invention should not be construed as being limited thereto.

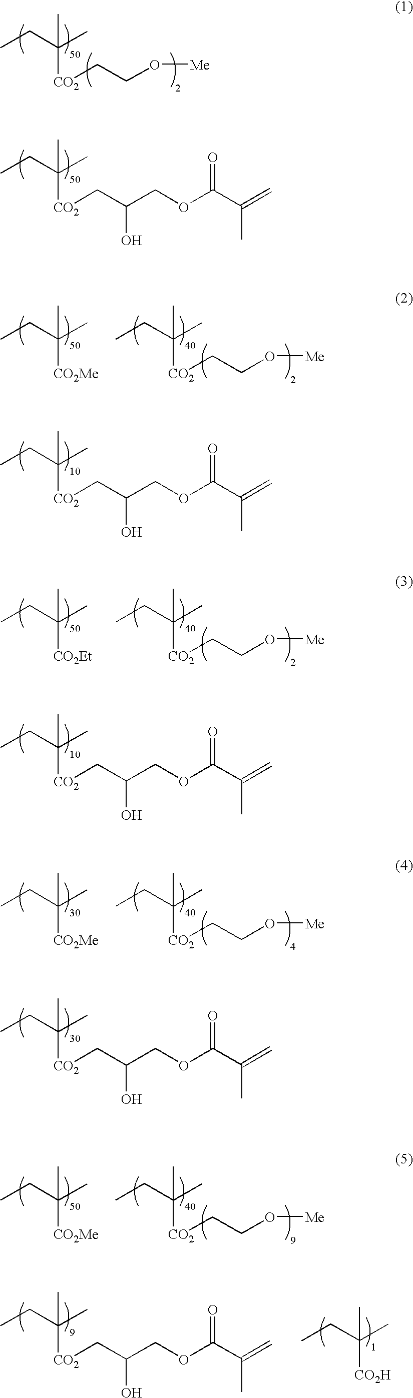

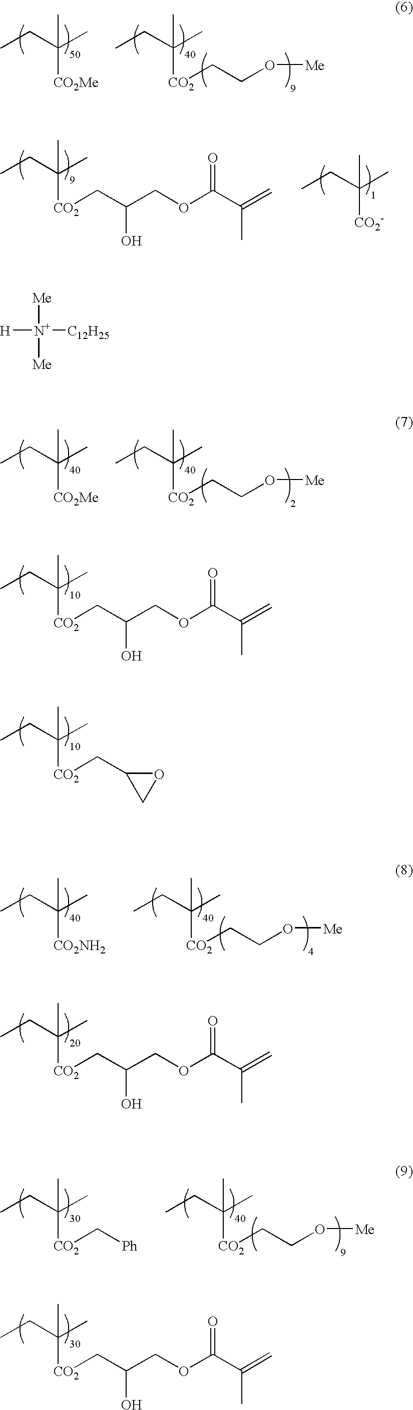

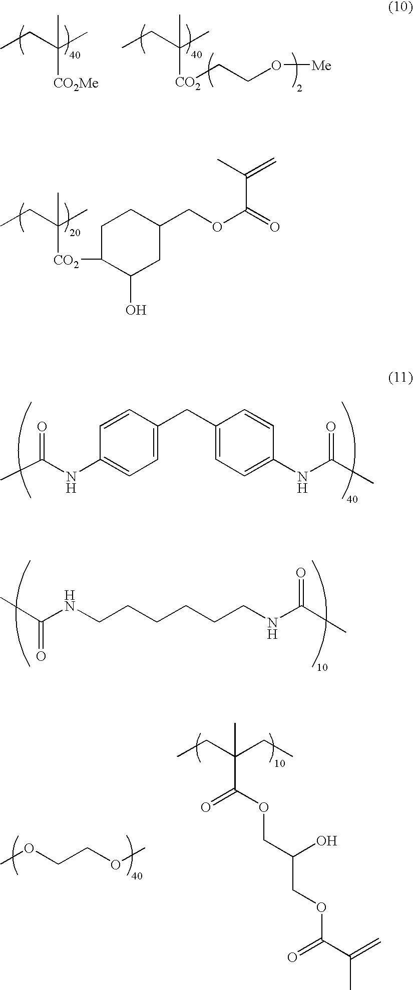

The weight average molecular weight (Mw) of the binder polymer according to the invention is preferably 2,000 or more, more preferably 5,000 or more, and still more preferably from 10,000 to 300,000.

According to the invention, a hydrophilic polymer, for example, polyacrylic acid or polyvinyl alcohol described in JP-A-2008-195018 may be used, if desired. Further, an oleophilic binder polymer is used together with a hydrophilic binder polymer.

The content of the binder polymer is preferably from 5 to 90% by weight, more preferably from 5 to 80% by weight, further more preferably from 10 to 70% by weight, based on the total solid content of the image-recording layer.

### (2) Hydrophilic Low Molecular Weight Compound

The image-recording layer according to the invention may further contain a hydrophilic low molecular weight compound in order to improve the on-press development property.

The hydrophilic low molecular weight compound includes a water-soluble organic compound, for example, a glycol compound, e.g., ethylene glycol, diethylene glycol, triethylene glycol, propylene glycol, dipropylene glycol or tripropylene glycol, or an ether or ester derivative thereof, a polyhydroxy compound, e.g., glycerine, pentaerythritol or tris(2-hydroxyethyl) isocyanurate, an organic amine compound, e.g., triethanol amine, diethanol amine or monoethanol amine, or a salt thereof, an organic sulfonic acid compound, e.g., an alkyl sulfonic acid, toluene sulfonic acid or benzene sulfonic acid, or a salt thereof, an organic sulfamic acid compound, e.g., an alkyl sulfamic acid, or a salt thereof, an organic sulfuric acid compound, e.g., an alkyl sulfuric acid or an alkyl ether sulfuric acid, or a salt thereof, an organic phosphonic acid compound, e.g., phenyl phosphonic acid, or a salt thereof, an organic carboxylic acid, e.g., tartaric acid, oxalic acid, citric acid, malic acid, lactic acid, gluconic acid or an amino acid, or a salt thereof and a betaine compound.

According to the invention, it is preferred that at least one compound selected from a polyol compound, an organic sulfate compound, an organic sulfonate compound and a betaine compound is incorporated.

Specific examples of the organic sulfonate compound include an alkylsulfonate, for example, sodium n-butylsulfonate, sodium n-hexylsulfonate, sodium 2-ethylhexylsulfonate, sodium cyclohexylsulfonate or sodium n-octylsulfonate; an alkylsulfonate containing an ethylene oxide chain, for example, sodium 5,8,11-trioxapentadecane-1-sulfate, sodium 5,8,11-trioxaheptadecane-1-sulfate, sodium 13-ethyl-5,8,11-trioxaheptadecane-1-sulfate or sodium 5,8,11,14-tetraoxatetracosane-1-sulfate; and an arylsulfonate, for example, sodium benzenesulfonate, sodium p-toluenesulfonate, sodium p-hydroxybenzenesulfonate, sodium p-styrenesulfonate, sodium isophthalic acid dimethyl-5-sulfonate, sodium 1-naphtylsulfonate, sodium 4-hydroxynaphtylsulfonate, disodium 1,5-naphtyldisulfonate or trisodium 1,3,6-naphtyltrisulfonate. The salt may also be potassium salt or lithium salt.

The organic sulfate compound includes a sulfate of alkyl, alkenyl, alkynyl, aryl or heterocyclic monoether of polyethylene oxide. The number of unit of ethylene oxide is preferably from 1 to 4. The salt is preferably a sodium salt, a potassium salt or a lithium salt.

As the betaine compound, a compound wherein a number of carbon atoms included in a hydrocarbon substituent on the nitrogen atom is from 1 to 5 is preferable. Specific examples thereof include trimethylammonium acetate, dimethylpropylammonium acetate, 3-hydroxy-4-trimethylammoniobutyrate, 4-(1-pyridinio)butyrate, 1-hydroxyethyl-1-imidazolioacetate, trimethylammonium methanesulfonate, dimethylpropylammonium methanesulfonate, 3-trimethylammonio-1-porpanesulfonate and 3-(1-pyridinio)-1-porpanesulfonate.

Since the hydrophilic low molecular weight compound has a small structure of hydrophobic portion and almost no surface active function, degradations of the hydrophobicity and film strength in the image area due to penetration of dampening water into the exposed area (image area) of the image-recording layer are prevented and thus, the ink receptive-property and printing durability of the image-recording layer can be preferably maintained.

The amount of the hydrophilic low molecular weight compound added to the image-recording layer is preferably from 0.5 to 20% by weight, more preferably from 1 to 10% by weight, still more preferably from 2 to 8% by weight, based on the total solid content of the image-recording layer. In the range described above, good on-press development property and good printing durability are achieved.

The hydrophilic low molecular weight compounds may be used individually or as a mixture of two or more thereof.

### (3) Oil-Sensitizing Agent

In order to improve the ink-receptive property, an oil-sensitizing agent, for example, a phosphonium compound, a nitrogen-containing low molecular weight compound or an ammonium group-containing polymer can be used in the image-recording layer. In particular, in the case where an inorganic stratiform compound is incorporated into a protective layer described hereinafter, the oil-sensitizing agent functions as a surface covering agent of the inorganic stratiform compound and prevents deterioration of the ink-receptive property during printing due to the inorganic stratiform compound.

As preferable examples of the phosphonium compound, phosphonium compounds described in JP-A-2006-297907 and JP-A-2007-50660 are exemplified. Specific examples of the phosphonium compound include tetrabutylphosphonium iodide, butyltriphenylphosphonium bromide, tetraphenylphosphonium bromide, 1,4-bis(triphenylphosphonio)butane di(hexafluorophosphate), 1,7-bis(triphenylphosphonio)heptane sulfate and 1,9-bis(triphenylphosphonio) nonane naphthalene-2,7-disulfonate.

As the nitrogen-containing low molecular weight compound, an amine salt and a quaternary ammonium salt are exemplified. Also, an imidazolinium salt, a benzimidazolinium salt, a pyridinium salt and a quinolinium salt are exemplified. Of the nitrogen-containing low molecular weight compounds, the quaternary ammonium salt and pyridinium salt are preferably used. Specific examples the nitrogen-containing low molecular weight compound include tetramethylammonium hexafluorophosphate, tetrabutylammonium hexafluorophosphate, dodecyltrimethylammonium p-toluenesulfonate, benzyltriethylammonium hexafluorophosphate, benzyldimethyloctylammonium hexafluorophosphate and benzyldimethyldodecylammonium hexafluorophosphate.

The ammonium group-containing polymer may be any polymer containing an ammonium group in its structure and is preferably a polymer containing from 5 to 80% by mole of (meth)acrylate having an ammonium group in its side chain as a copolymerization component.

As to the ammonium group-containing polymer, its reduced specific viscosity value (unit: cSt/g/ml) determined according to the measuring method described below is preferably from 5 to 120, more preferably from 10 to 110, particularly preferably from 15 to 100.

### <Measuring Method of Reduced Specific Viscosity>

In a 20 ml measuring flask was weighed 3.33 g of a 30% polymer solution (1 g as a solid content) and the measuring flask was filled up to the gauge line with N-methylpyrrolidone. The resulting solution was put into an Ubbelohde viscometer (viscometer constant: 0.010 cSt/s) and a period for running down of the solution at 30° C. was measured. The viscosity was determined in a conventional manner according to the following calculating formula:

Kinetic viscosity=Viscometer constant×Period for liquid to pass through a capillary (sec)

Specific examples of the ammonium group-containing polymer are set forth below.

(1) 2-(Trimethylammonio)ethyl methacrylate p-toluenesulfonate/3,6-dioxaheptyl methacrylate copolymer (molar ratio: 10/90)
(2) 2-(Trimethylammonio)ethyl methacrylate hexafluorophosphate/3,6-dioxaheptyl methacrylate copolymer (molar ratio: 20/80)
(3) 2-(Ethyldimethylammonio)ethyl methacrylate p-toluenesulfonate/hexyl methacrylate copolymer (molar ratio: 30/70)
(4) 2-(Trimethylammonio)ethyl methacrylate hexafluorophosphate/2-ethylhexyl methacrylate copolymer (molar ratio: 20/80)
(5) 2-(Trimethylammonio)ethyl methacrylate methylsulfate/hexyl methacrylate copolymer (molar ratio: 40/60)
(6) 2-(Butyldimethylammonio)ethyl methacrylate hexafluorophosphate/3,6-dioxaheptyl methacrylate copolymer (molar ratio: 20/80)
(7) 2-(Butyldimethylammonio)ethyl acrylate hexafluorophosphate/3,6-dioxaheptyl methacrylate copolymer (molar ratio: 20/80)
(8) 2-(Butyldimethylammonio)ethyl methacrylate 13-ethyl-5,8,11-trioxa-1-heptadecanesulfonate/3,6-dioxaheptyl methacrylate copolymer (molar ratio: 20/80)
(9) 2-(Butyldimethylammonio)ethyl methacrylate hexafluorophosphate/3,6-dioxaheptyl methacrylate/2-hydroxy-3-methacryloyloxypropyl methacrylate copolymer (molar ratio: 15/80/5)

The content of the oil-sensitizing agent is preferably from 0.01 to 30.0% by weight, more preferably from 0.1 to 15.0% by weight, still more preferably from 1 to 5% by weight, based on the total solid content of the image-recording layer.

### (4) Other Components

Other components, for example, a surfactant, a coloring agent, a print-out agent, a polymerization inhibitor, a higher fatty acid derivative, a plasticizer, a fine inorganic particle, an inorganic stratiform compound, a co-sensitizer or a chain transfer agent may further be added to the image-recording layer. Specifically, compounds and amounts added thereof described, for example, in Paragraph Nos. [0114] to [0159] of JP-A-2008-284817, Paragraph Nos. [0023] to [0027] of JP-A-2006-91479 and Paragraph No. [0060] of U.S. Patent Publication No. 2008/0311520 are preferably used.

### <(G) Formation of Image-Recording Layer>

The image-recording layer according to the invention is formed by dispersing or dissolving each of the necessary constituting components described above in a solvent to prepare a coating solution and coating the solution on a support by a known method, for example, bar coater coating and drying as described in Paragraph Nos. [0142] to [0143] of JP-A-2008-195018. The coating amount (solid content) of the image-recording layer formed on a support after coating and drying may be varied according to the intended purpose but is in general preferably from 0.3 to 3.0 g/m². In the range described above, good sensitivity and good film property of the image-recording layer can be achieved.

### (Undercoat Layer)

In the lithographic printing plate precursor according to the invention, an undercoat layer (also referred to as an intermediate layer) is preferably provided between the image-recording layer and the support. The undercoat layer strengthens adhesion between the support and the image-recording layer in the exposed area and makes removal of the image-recording layer from the support in the unexposed area easy, thereby contributing improvement in the developing property without accompanying degradation of the printing durability. Further, it is advantageous that in the case of infrared laser exposure, since the undercoat layer acts as a heat insulating layer, decrease in sensitivity due to diffusion of heat generated upon the exposure into the support is prevented.

As a compound for use in the undercoat layer, specifically, for example, a silane coupling agent having an addition-polymerizable ethylenic double bond reactive group described in JP-A-10-282679 and a phosphorus compound having an ethylenic double bond reactive group described in JP-A-2-304441 are preferably exemplified. A polymer resin having an adsorbing group capable of adsorbing to a surface of the support, a hydrophilic group and a crosslinkable group as described in JP-A-2005-125749 and JP-A-2006-188038 is more preferably exemplified. The polymer resin is preferably a copolymer of a monomer having an adsorbing group, a monomer having a hydrophilic group and a monomer having a crosslinkable group. More specifically, a polymer resin which is a copolymer of a monomer having an adsorbing group, for example, a phenolic hydroxy group, a carboxyl group, —PO₃H₂, —OPO₃H₂, —CONHSO₂—, —SO₂NHSO₂— and —COCH₂COCH₃, a monomer having a hydrophilic sulfo group and a monomer having a polymerizable crosslinkable group, for example, a methacryl group or an allyl group. The polymer resin may contain a crosslinkable group introduced by a salt formation between a polar substituent of the polymer resin and a compound containing a substituent having a counter charge to the polar substituent of the polymer resin and an ethylenically unsaturated bond and also may be further copolymerized with a monomer other than those described above, preferably a hydrophilic monomer.

The content of the unsaturated double bond in the polymer resin for undercoat layer is preferably from 0.1 to 10.0 mmol, most preferably from 2.0 to 5.5 mmol, based on 1 g of the polymer resin.

The weight average molecular weight of the polymer resin for undercoat layer is preferably 5,000 or more, more preferably from 10,000 to 300,000.

The undercoat layer according to the invention may contain a chelating agent, a secondary or tertiary amine, a polymerization inhibitor or a compound containing an amino group or a functional group having polymerization inhibition ability and a group capable of interacting with the surface of aluminum support (for example, 1,4-diazobicyclo[2,2,2]octane (DABCO), 2,3,5,6-tetrahydroxy-p-quinone, chloranil, sulfophthalic acid, hydroxyethylenediaminetriacetic acid, dihydroxyethylenediaminediacetic acid or hydroxyethyliminodiacetic acid) in addition to the compounds for the undercoat layer described above in order to prevent the occurrence of stain due to preservation of the lithographic printing plate precursor.

The undercoat layer is coated according to a known method. The coating amount (solid content) of the undercoat layer is preferably from 0.1 to 100 mg/m², and more preferably from 1 to 30 mg/m².

### (Support)

As the support for use in the lithographic printing plate precursor according to the invention, a known support is used. Particularly, an aluminum plate subjected to roughening treatment and anodizing treatment according to a known method is preferable.

Also, other treatments, for example, an enlarging treatment or a sealing treatment of micropores of the anodized film described in JP-A-2001-253181 and JP-A-2001-322365 or a surface hydrophilizing treatment, for example, with an alkali metal silicate as described in U.S. Pat. Nos. 2,714,066, 3,181,461, 3,280,734 and 3,902,734 or polyvinyl phosphonic acid as described in U.S. Pat. Nos. 3,276,868, 4,153,461 and 4,689,272 may be appropriately selected and applied to the aluminum plate, if desired.

The support preferably has a center line average roughness of 0.10 to 1.2 μm.

The support may have a backcoat layer containing an organic polymer compound described in JP-A-5-45885 or an alkoxy compound of silicon described in JP-A-5-45885, provided on the back surface thereof, if desired.

### (Protective Layer)

In the lithographic printing plate precursor according to the invention, it is preferred to provide a protective layer (overcoat layer) on the image-recording layer. The protective layer has a function for preventing, for example, occurrence of scratch in the image-recording layer or ablation caused by exposure with a high illuminance laser beam, in addition to the function for restraining an inhibition reaction against the image formation by means of oxygen blocking.

With respect to the protective layer having such properties, there are described, for example, in U.S. Pat. No. 3,458,311 and JP-B-55-49729 (the term “JP-B” as used herein means an “examined Japanese patent publication”). As a polymer having low oxygen permeability for use in the protective layer, any water-soluble polymer and water-insoluble polymer can be appropriately selected to use. Specifically, for example, polyvinyl alcohol, a modified polyvinyl alcohol, polyvinyl pyrrolidone, a water-soluble cellulose derivative and poly(meth)acrylonitrile are exemplified.

It is also preferred that the protective layer contains an inorganic stratiform compound, for example, natural mica or synthetic mica as described in JP-A-2005-119273 in order to increase the oxygen blocking property.

Further, the protective layer may contain a known additive, for example, a plasticizer for imparting flexibility, a surfactant for improving a coating property or a fine inorganic particle for controlling a surface slipping property. The oil-sensitizing agent described with respect to the image-recording layer may also be incorporated into the protective layer.

The protective layer is coated according to a known method. The coating amount of the protective layer is preferably in a range of 0.01 to 10 g/m², more preferably in a range of 0.02 to 3 g/m², most preferably in a range of 0.02 to 1 g/m², in terms of the coating amount after drying.

### [Plate Making Method]

Plate making of the lithographic printing plate precursor according to the invention is preferably performed by an on-press development method. The on-press development method includes a step in which the lithographic printing plate precursor is imagewise exposed and a printing step in which oily ink and an aqueous component are supplied to the exposed lithographic printing plate precursor without undergoing any development processing to perform printing, and it is characterized in that the unexposed area of the lithographic printing plate precursor is removed in the course of the printing step. The imagewise exposure may be performed on a printing machine after the lithographic printing plate precursor is mounted on the printing machine or may be separately performed using a platesetter or the like. In the latter case, the exposed lithographic printing plate precursor is mounted as it is on a printing machine without undergoing a development processing step. Then, the printing operation is initiated using the printing machine with supplying oily ink and an aqueous component and at an early stage of the printing the on-press development is carried out. Specifically, the image-recording layer in the unexposed area is removed and the hydrophilic surface of support is revealed therewith to form the non-image area. As the oily ink and aqueous component, printing ink and dampening water for conventional lithographic printing can be employed, respectively.

The on-press development method is described in more detail below.

As the light source used for the image exposure in the invention, a laser is preferable. The laser for use in the invention is not particularly restricted and includes, for example, a solid laser or semiconductor laser emitting an infrared ray having a wavelength of 760 to 1,200 nm.

With respect to the infrared ray laser, the output is preferably 100 mW or more, the exposure time per pixel is preferably within 20 microseconds, and the irradiation energy is preferably from 10 to 300 mJ/cm². With respect to the laser exposure, in order to shorten the exposure time, it is preferred to use a multibeam laser device.

The exposed lithographic printing plate precursor is mounted on a plate cylinder of a printing machine. In case of using a printing machine equipped with a laser exposure apparatus, the lithographic printing plate precursor is mounted on a plate cylinder of the printing machine and then subjected to the imagewise exposure.

When oily ink and an aqueous component are supplied to the imagewise exposed lithographic printing plate precursor to perform printing, in the exposed area of the image-recording layer, the image-recording layer cured by the exposure forms the oily ink receptive area having the oleophilic surface. On the other hand, in the unexposed area, the uncured image-recording layer is removed by dissolution or dispersion with the oily ink and/or aqueous component supplied to reveal the hydrophilic surface in the area. As a result, the aqueous component adheres on the revealed hydrophilic surface and the oily ink adheres to the exposed area of the image-recording layer, whereby printing is initiated.

While either the aqueous component or oily ink may be supplied at first on the surface of lithographic printing plate precursor, it is preferred to supply the oily ink at first in view of preventing the aqueous component from contamination with the component of the image-recording layer removed.

As the oily ink, printing ink for use in conventional lithographic printing, UV ink or the like is used. As the aqueous component, dampening water for use in conventional lithographic printing is used.

Thus, the lithographic printing plate precursor according to the invention is subjected to the on-press development on an offset printing machine and used as it is for printing a large number of sheets.

### EXAMPLES

The present invention will be described in more detail with reference to the following examples, but the invention should not be construed as being limited thereto.

1. Preparation of Lithographic Printing Plate Precursors (1) to (15) (photopolymerizable Type)

### (1) Preparation of Support

An aluminum plate (material: JIS A 1050) having a thickness of 0.3 mm was subjected to a degreasing treatment at 50° C. for 30 seconds using a 10% by weight aqueous sodium aluminate solution in order to remove rolling oil on the surface thereof and then grained the surface thereof using three nylon brushes embedded with bundles of nylon bristle having a diameter of 0.3 mm and an aqueous suspension (specific gravity: 1.1 g/cm³) of pumice having a median size of 25 μm, followed by thorough washing with water. The plate was subjected to etching by immersing in a 25% by weight aqueous sodium hydroxide solution of 45° C. for 9 seconds, washed with water, then immersed in a 20% by weight aqueous nitric acid solution at 60° C. for 20 seconds, and washed with water. The etching amount of the grained surface was about 3 g/m².

Then, using an alternating current of 60 Hz, an electrochemical roughening treatment was continuously carried out on the plate. The electrolytic solution used was a 1% by weight aqueous nitric acid solution (containing 0.5% by weight of aluminum ion) and the temperature of electrolytic solution was 50° C. The electrochemical roughening treatment was conducted using an alternating current source, which provides a rectangular alternating current having a trapezoidal waveform such that the time TP necessary for the current value to reach the peak from zero was 0.8 msec and the duty ratio was 1:1, and using a carbon electrode as a counter electrode. A ferrite was used as an auxiliary anode. The current density was 30 A/dm² in terms of the peak value of the electric current, and 5% of the electric current flowing from the electric source was divided to the auxiliary anode. The quantity of electricity in the nitric acid electrolysis was 175 C/dm² in terms of the quantity of electricity when the aluminum plate functioned as an anode. The plate was then washed with water by spraying.

The plate was further subjected to an electrochemical roughening treatment in the same manner as in the nitric acid electrolysis above using as an electrolytic solution, a 0.5% by weight aqueous hydrochloric acid solution (containing 0.5% by weight of aluminum ion) having temperature of 50° C. and under the condition that the quantity of electricity was 50 C/dm² in terms of the quantity of electricity when the aluminum plate functioned as an anode. The plate was then washed with water by spraying.

The plate was then subjected to an anodizing treatment using as an electrolytic solution, a 15% by weight aqueous sulfuric acid solution (containing 0.5% by weight of aluminum ion) at a current density of 15 A/dm² to form a direct current anodized film of 2.5 g/m², washed with water and dried.

Thereafter, in order to ensure the hydrophilicity of the non-image area, the plate was subjected to silicate treatment using a 2.5% by weight aqueous sodium silicate No. 3 solution at 70° C. for 12 seconds and washed with water to prepare Support (1). The adhesion amount of Si was 10 mg/m². The center line average roughness (Ra) of the support was measured using a stylus having a diameter of 2 μm and found to be 0.51 μm.

### (2) Formation of Undercoat Layer (1)

Coating solution (1) for undercoat layer shown below was coated on Support (1) so as to have a dry coating amount of 28 mg/m² to prepare Undercoat layer (1).

### <Coating Solution (1) for Undercoat Layer>

| | |
|---|---|
| Compound (1) for undercoat layer having structure | 0.18 g |
| shown below | |
| Hydroxyethyliminodiacetic acid | 0.10 g |
| Methanol | 55.24 g |
| Water | 6.15 g |

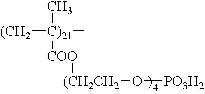

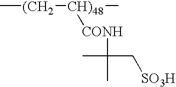

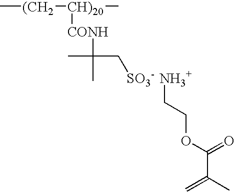

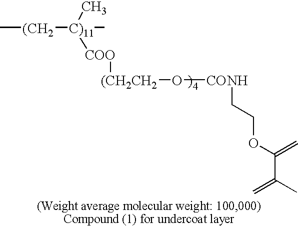

### (3) Formation of Image-Recording Layers (1) to (15)

Coating solutions (1) to (15) for image-recording layer having the composition shown below were coated on the undercoat layer described above by a bar and dried in an oven at 100° C. for 60 seconds to form Image-recording layers (1) to (15) each having a dry coating amount of 1.0 g/m², respectively.

Coating solutions (1) to (15) for image-recording layer were prepared by mixing Photosensitive solutions (1) to (15) shown below with Microgel solution (1) shown below just before the coating, followed by stirring, respectively.

### <Photosensitive Solutions (1) to (15)>

| | |
|---|---|
| Binder polymer (1) having structure shown | 0.24 g |
| above | |
| Infrared absorbing agent (1) having structure | 0.030 g |
| shown below | |
| Radical initiator (1) having structure shown | 0.162 g |
| below | |
| Radical polymerizable compound | 0.192 g |
| (Tris(acryloyloxyethyl) isocyanurate (NK | |
| Ester A-9300, produced by Shin-Nakamura | |
| Chemical Co., Ltd.)) | |
| Component (A) according to the invention shown | 0.062 g |
| in Table 6 | |
| Hydrophilic low molecular weight compound (1) | 0.050 g |
| having structure shown below | |
| Ammonium group-containing polymer having | 0.055 g |
| structure shown below (reduced specific | |
| viscosity: 44 cSt/g/ml) | |
| Benzyl dimethyl octyl ammonium PF₆ salt | 0.018 g |
| Betaine having structure shown below | 0.005 g |
| Fluorine-based surfactant (1) having | 0.008 g |
| structure shown below | |
| 2-Butanone | 1.091 g |
| 1-Methoxy-2-propanol | 8.609 g |

### <Microgel Solution (1)>

| | |
|---|---|
| Microgel (1) shown below | 2.640 g |
| Distilled water | 2.425 g |

The structures of Binder polymer (1), Infrared absorbing agent (1), Radical initiator (1), Hydrophilic low molecular weight compound (1), Fluorine-based surfactant (1), Ammonium group-containing polymer and Betaine are shown below.

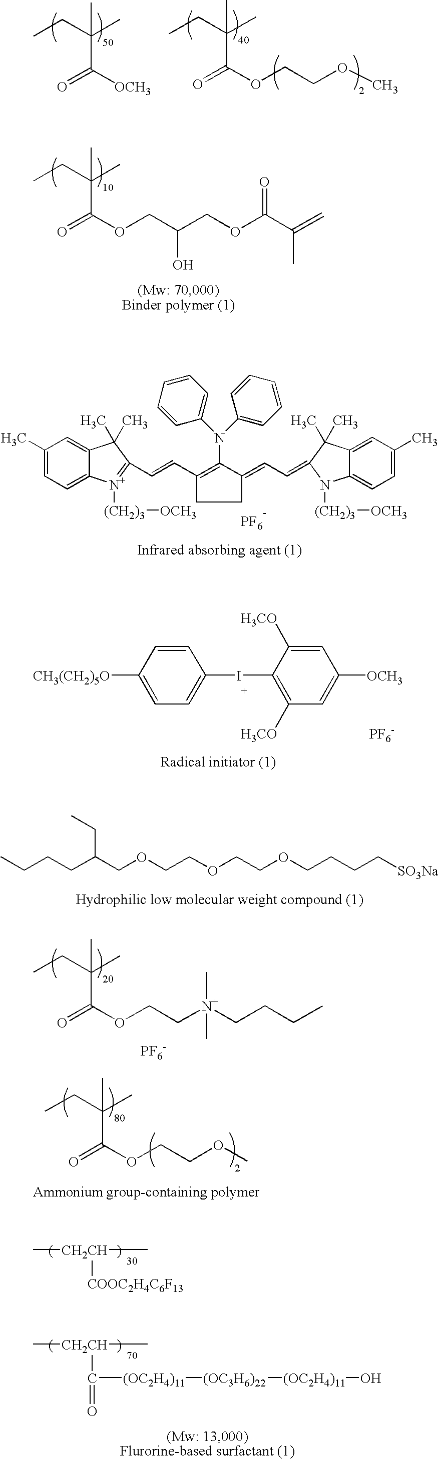

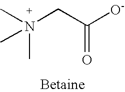

Microgel (1) was prepared in the following manner.

### <Preparation of Microgel (1)>

An oil phase component was prepared by dissolving 10 g of adduct of trimethylol propane and xylene diisocyanate (Takenate D-110N, produced by Mitsui Chemicals Polyurethanes, Inc.), 3.15 g of pentaerythritol triacrylate (SR444, produced by Nippon Kayaku Co., Ltd.) [Component (D)] and 0.1 g of Pionin A-41C (produced by Takemoto Oil & Fat Co., Ltd.) in 17 g of ethyl acetate. As an aqueous phase component, 40 g of a 4% by weight aqueous solution of PVA-205 was prepared. The oil phase component and the aqueous phase component were mixed and emulsified using a homogenizer at 12,000 rpm for 10 minutes. The resulting emulsion was added to 25 g of distilled water and stirred at room temperature for 30 minutes and then at 50° C. for 3 hours. The microgel liquid thus-obtained was diluted using distilled water so as to have the solid concentration of 15% by weight to prepare Microgel (1). The average particle size of the microgel was measured by a light scattering method and found to be 0.2 μm.

### (4) Formation of Protective Layer (1)

Coating solution (1) for protective layer having the composition shown below was coated on Image-recording layers (1) to (15) described above by a bar and dried in an oven at 120° C. for 60 seconds to form a protective layer having a dry coating amount of 0.15 g/m², thereby preparing Lithographic printing plate precursors (1) to (15), respectively.

### <Coating Solution (1) for Protective Layer>

| | |
|---|---|
| Dispersion of inorganic stratiform compound | 1.5 g |
| (1) shown below | |
| Aqueous 6% by weight solution of polyvinyl | 0.55 g |
| alcohol (CKS 50, sulfonic acid-modified, | |
| saponification degree: 99% by mole or more, | |
| polymerization degree: 300, produced by Nippon | |
| Synthetic Chemical Industry Co., Ltd.) | |
| Aqueous 6% by weight solution of polyvinyl | 0.03 g |
| alcohol (PVA-405, saponification degree: | |
| 81.5% by mole, polymerization degree: 500, | |
| produced by Kuraray Co., Ltd.) | |
| Aqueous 1% by weight solution of surfactant | 0.86 g |
| (Emalex 710, produced by Nihon Emulsion Co., | |
| Ltd.) | |
| Ion-exchanged water | 6.0 g |

### <Preparation of Dispersion of Inorganic Stratiform Compound (1)>

To 193.6 g of ion-exchanged water was added 6.4 g of synthetic mica (Somasif ME-100, produced by CO—OP Chemical Co., Ltd.) and the mixture was dispersed using a homogenizer until an average particle size (according to a laser scattering method) became 3 μm to prepare Dispersion of inorganic stratiform compound (1). The aspect ratio of the inorganic particle thus-dispersed was 100 or more.

### 3. Preparation of Lithographic Printing Plate Precursors (21) to (25)

Coating solutions (21) to (25) for image-recording layer shown below were coated on the undercoat layer described above by a bar and dried in an oven at 70° C. for 60 seconds to form Image-recording layers (21) to (25) each having a dry coating amount of 0.6 g/m², respectively, thereby preparing Lithographic printing plate precursors (21) to (25), respectively.

### <Coating Solutions (21) to (25) for Image-Recording Layer>

| | |
|---|---|
| Aqueous dispersion of fine polymer particle | 20.0 g |
| (2) shown below | |
| Infrared absorbing dye (3) having structure | 0.2 g |
| shown below | |
| Radical initiator (Irgacure 250, produced by | 0.5 g |
| Ciba Specialty Chemicals, Inc.) | |
| Component (A) according to the invention shown | 0.8 g |
| in Tbale 6 | |
| Radical polymerizable compound (SR-399, | 1.50 g |
| produced by Sartomer Co.) | |
| Mercapto-3-triazole | 0.2 g |
| BYK 336 (produced by BYK-Chemie GmbH) | 0.4 g |
| Klucel M (produced by Hercules Chemical Co., | 4.8 g |
| Inc.) | |
| Elvacite 4026 (produced by Ineos Acrylics | 2.5 g |
| Inc.) | |
| n-Propanol | 55.0 g |
| 2-Butanone | 17.0 g |

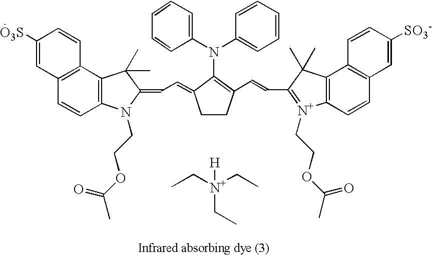

The compounds indicated using their trade names in the composition above are shown below.

### Irgacure 250:

(4-Methoxyphenyl) [4-(2-methylpropyl)phenyl]iodonium hexafluorophosphate (75% by weight propylene carbonate solution)
SR-399: Dipentaerythritol pentaacrylate
BYK 336: Modified dimethylpolysiloxane copolymer (25% by weight xylene/methoxypropyl acetate solution)
Klucel M: Hydroxypropyl cellulose (2% by weight aqueous solution)
Elvacite 4026: Highly branched polymethyl methacrylate (10% by weight 2-butanone solution)

### (Preparation of Aqueous Dispersion of Fine Polymer Particle (2))

A stirrer, a thermometer, a dropping funnel, a nitrogen inlet tube and a reflux condenser were attached to a 1,000 ml four-neck flask and while carrying out deoxygenation by introduction of nitrogen gas, 20 g of polyethylene glycol methyl ether methacrylate (PEGMA), 200 g of distilled water and 200 g of n-propanol were charged therein and heated until the internal temperature reached 70° C. Then, a mixture of 10 g of styrene (St), 80 g of acrylonitrile (AN) and 0.8 g of 2,2′-azobisisobutyronitrile previously prepared was dropwise added to the flask over a period of one hour. After the completion of the dropwise addition, the reaction was continued as it was for 5 hours. Then, 0.4 g of 2,2′-azobisisobutyronitrile was added and the internal temperature was raised to 80° C. Thereafter, 0.5 g of 2,2′-azobisisobutyronitrile was added over a period of 6 hours. At the stage after reacting for 20 hours in total, the polymerization proceeded 98% or more to obtain Aqueous dispersion of fine polymer particle (1) of PEGMA/St/AN (18/9/73 in a weight ratio). The particle size distribution of the fine particle polymer had the maximum value at the particle size of 150 nm.

The particle size distribution was determined by taking an electron microphotograph of the fine polymer particles, measuring particle sizes of 5,000 fine particles in total on the photograph, and dividing a range from the largest value of the particle size measured to 0 on a logarithmic scale into 50 parts to obtain occurrence frequency of each particle size by plotting. With respect to the aspherical particle, a particle size of a spherical particle having a particle area equivalent to the particle area of the aspherical particle on the photograph was defined as the particle size.

### 4. Preparation of Lithographic Printing Plate Precursors (R-1) and (R-2) for Comparative Examples 1 and 2

Lithographic printing plate precursor (R-1) for Comparative Example 1 was prepared in the same manner as in the preparation of Lithographic printing plate precursor (1) except for changing Component (A) in Photosensitive solution (1) for Coating solution (1) for Image-recording layer to Comparative compound (C-1) shown below.

Lithographic printing plate precursor (R-2) for Comparative Example 2 was prepared in the same manner as in the preparation of Lithographic printing plate precursor (21) except for changing Component (A) in Coating solution (21) for Image-recording layer to Comparative compound (C-1) shown below.

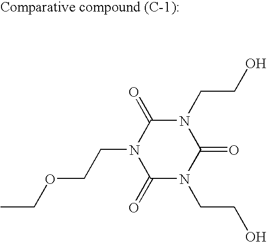

### Examples 1 to 15 and Comparative Example 1

The on-press development property and printing durability of Lithographic printing plate precursors (1) to (15) and Lithographic printing plate precursor (R-1) for comparative example thus-obtained were evaluated in the manner described below. The results obtained are shown in Table 6.

### (1) On-Press Development Property

Each of the lithographic printing plate precursors thus-obtained was exposed by Luxel Platesetter T-6000III equipped with an infrared semiconductor laser, produced by Fuji Film Co., Ltd. under the conditions of a rotational number of an outer surface drum of 1,000 rpm, laser output of 70% and resolution of 2,400 dpi. The exposed image contained a solid image and a 50% halftone dot chart of a 20 μm-dot FM screen.

The exposed lithographic printing plate precursor was mounted without undergoing development processing on a plate cylinder of a printing machine (Lithrone 26, produced by Komori Corp.). Using dampening water (Ecolity-2 (produced by Fuji Film Co., Ltd.)/tap water=2/98 (volume ratio)) and Bestcure UV-BF-WRO standard black ink (produced by T & K Toka Co., Ltd.), the dampening water and ink were supplied according to the standard automatic printing start method of Lithrone 26 to conduct on-press development and printing on 100 sheets of Tokubishi art paper (76.5 kg) at a printing speed of 10,000 sheets per hour.

A number of the printing papers required until the on-press development of the unexposed area of the image-recording layer on the printing machine was completed to reach a state where the ink was not transferred to the printing paper in the non-image area was measured and the on-press development property was determined according to the formula shown below using the number of the printing papers of Lithographic printing plate precursor (R-1) for comparative example as the criterion (100). As the value increases, the on-press development property becomes better.

On-press development property=(Number of the printing papers of criterion lithographic printing plate precursor)/(Number of the printing papers of subject lithographic printing plate precursor)×100

(2) Printing Durability with UV Ink

After performing the evaluation for the on-press development property described above, the printing was continued. As the increase in a number of printing papers, the image-recording layer was gradually abraded to cause decrease in the ink density on the printing paper. A number of printing papers wherein a value obtained by measuring a halftone dot area rate of the 50% halftone dot of FM screen on the printing paper using a Gretag densitometer decreased by 5% from the value measured on the 100^{th} paper of the printing was measured and the printing durability was determined according to the formula shown below using the number of the printing papers of Lithographic printing plate precursor (R-1) for comparative example as the criterion (100). As the value increases, the printing durability becomes better.

Printing durability with UV ink=(Number of the printing papers of subject lithographic printing plate precursor)/(Number of the printing papers of criterion lithographic printing plate precursor)×100

### (3) On-Press Development Property After Preservation

The lithographic printing plate precursor was preserved at 60° C. for 3 days and then the on-press development property was evaluated in the same manner as described above. As the criterion (100), the number of the printing papers of Lithographic printing plate precursor (R-1) for comparative example without the preservation was used. As the value increases, the on-press development property after preservation becomes better.

### Examples 21 to 25 and Comparative Example 2

The on-press development property and printing durability of Lithographic printing plate precursors (21) to (25) and Lithographic printing plate precursor (R-2) for comparative example were evaluated in the manner as in Examples 1 to 15 and Comparative Example 1. As the criterion (100), Lithographic printing plate precursor (R-2) for comparative example was used. The results obtained are shown in Table 6.

TABLE 6
Examples 1 to 15 and 21 to 25 and Comparative Examples 1 and 2

| | | | | On-press Development | |
|---|---|---|---|---|---|
| | Lithographic | Component (A) | On-press | Property after | Printing |
| | Printing Plate | or Comparative | Development | Preservation at 60° C. | Durability |
| | Precursor | Compound | Property | for 3 Days | with UV Ink |
| Example 1 | (1) | A-2 | 110 | 95 | 220 |
| Comparative | (R-1) | C-1 | 100 | 20 | 100 |
| Example 1 | | | | | |
| Example 2 | (2) | A-17 | 110 | 95 | 240 |
| Example 3 | (3) | A-19 | 100 | 90 | 250 |
| Example 4 | (4) | A-21 | 100 | 80 | 210 |
| Example 5 | (5) | A-34 | 120 | 85 | 230 |
| Example 6 | (6) | A2a-1 | 110 | 100 | 260 |
| Example 7 | (7) | A2a-2 | 105 | 100 | 250 |
| Example 8 | (8) | A2a-3 | 110 | 100 | 250 |
| Example 9 | (9) | A2a-4 | 120 | 105 | 260 |
| Example 10 | (10) | A2a-5 | 115 | 100 | 240 |
| Example 11 | (11) | A2b-2 | 110 | 95 | 240 |
| Example 12 | (12) | A2b-5 | 120 | 105 | 230 |
| Example 13 | (13) | A2b-6 | 115 | 100 | 235 |
| Example 14 | (14) | A2b-8 | 100 | 90 | 240 |
| Example 15 | (15) | A2b-11 | 120 | 100 | 225 |
| Example 21 | (21) | A2a-1 | 100 | 95 | 190 |
| Comparative | (R-2) | C-1 | 100 | 40 | 100 |
| Example 2 | | | | | |
| Example 22 | (22) | A2a-2 | 100 | 95 | 180 |
| Example 23 | (23) | A2a-3 | 100 | 95 | 180 |
| Example 24 | (24) | A2a-4 | 110 | 105 | 190 |
| Example 25 | (25) | A2a-5 | 105 | 100 | 170 |

The component (A) and comparative compound shown in Table 6 are described below.

(1) The number of “A-” indicates the number of specific examples of the compounds shown in Tables 1 and 2 hereinbefore.
(2) The number of “A2b-” indicates the number of specific examples of the compounds (reaction products) shown in Tables 3 to 5 hereinbefore. Weight average molecular weights (Mw) of these compounds are shown below. In each compound, a reaction rate of the polyfunctional carboxylic acid and polyfunctional epoxy compound was 50:50 and the unreacted carboxyl group was resolved by adding glycidol after the completion of the reaction.

A2b-2 Mw: 25,000

A2b-5 Mw: 16,000

A2b-6 Mw: 19,000

A2b-8 Mw: 15,000

A2b-11 Mw: 5,000

(3) The structures of the polymers indicated by the number of “A2a-” are shown below.

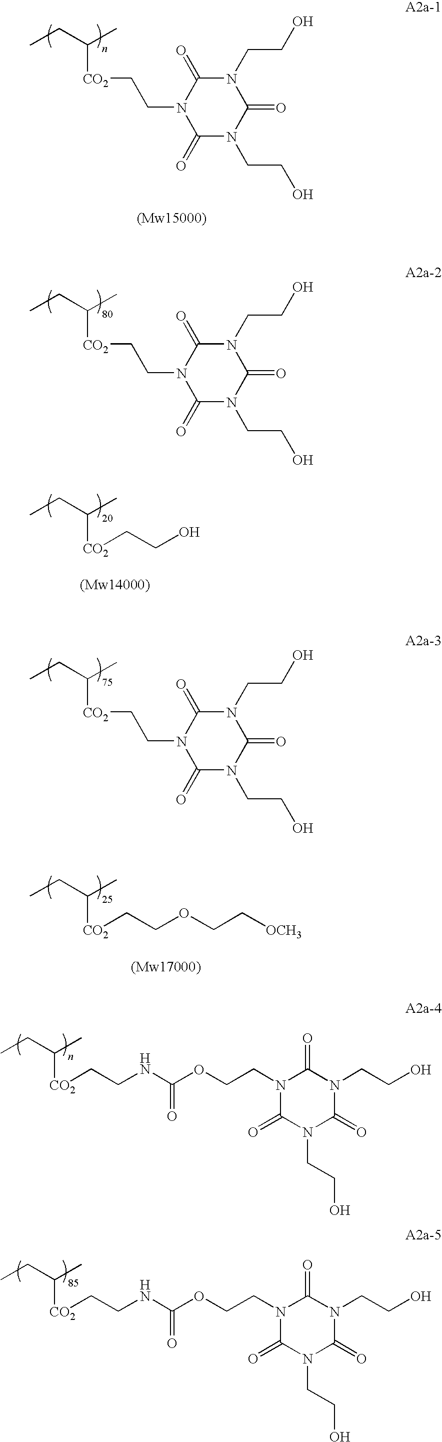

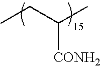

As is apparent from the results shown in Table 6, the remarkable effects on the prevention of degradation of on-press development property after preservation of the lithographic printing plate precursor and the printing durability with UV ink are achieved according to the present invention.

What is claimed is:

1. A lithographic printing plate precursor comprising:
a support; and
an image-recording layer, a non-image area of which is capable of being removed by supplying printing ink and dampening water, and which comprises (A) a compound containing two or more isocyanuric acid skeletons each having at least one substituent containing a hydroxy group, (B) an infrared absorbing agent, (C) a radical initiator and (D) a radical polymerizable compound.

2. The lithographic printing plate precursor as claimed in claim 1, wherein the compound containing two or more isocyanuric acid skeletons each having at least one substituent containing a hydroxy group is a compound represented by the following formula (I): 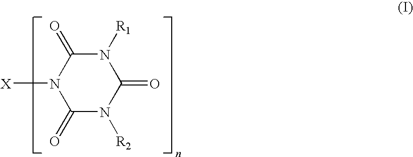
wherein R₁ and R₂ each independently represents a hydrogen atom, an alkyl group, an aryl group or an aralkyl group, provided that at least one of R₁ and R₂ is an alkyl group, aryl group or aralkyl group substituted with a hydroxy group, X represents an n-valent group comprising a combination of atoms selected from a carbon atom, a hydrogen atom, an oxygen atom, a nitrogen atom and a sulfur atom, and n represents an integer of from 2 or 10.

3. The lithographic printing plate precursor as claimed in claim 1, wherein the compound containing two or more isocyanuric acid skeletons each having at least one substituent containing a hydroxy group is a polymer having a repeating unit containing an isocyanuric acid skeleton having at least one substituent containing a hydroxy group.

4. The lithographic printing plate precursor as claimed in claim 3, wherein the polymer is a vinyl polymer having a repeating unit containing an isocyanuric acid skeleton having at least one substituent containing a hydroxy group in a side chain.

5. The lithographic printing plate precursor as claimed in claim 3, wherein the polymer is a polymer which has a repeating unit containing an isocyanuric acid skeleton having at least one substituent containing a hydroxy group in a main chain and is obtained by an addition reaction between a polyfunctional carboxylic acid and a polyfunctional epoxy compound.

6. The lithographic printing plate precursor as claimed in claim 1, wherein the image-recording layer further comprises a hydrophobilizing precursor.

7. The lithographic printing plate precursor as claimed in claim 6, wherein the hydrophobilizing precursor is at least one of a microcapsule and a microgel.

8. The lithographic printing plate precursor as claimed in claim 1, wherein the radical polymerizable compound is a compound having an isocyanuric acid skeleton.

9. The lithographic printing plate precursor as claimed in claim 1, which further comprises a protective layer, so that the support, the image-recording layer and the protective layer are provided in this order.

10. The lithographic printing plate precursor as claimed in claim 9, wherein the protective layer comprises an inorganic stratiform compound.

11. A plate making method comprising:
exposing imagewise the lithographic printing plate precursor as claimed in claim 1; and
removing an unexposed area of the image-recording layer by supplying oily ink and an aqueous component on a printing machine without applying any development processing to the exposed lithographic printing plate precursor.
